(19) United States
(12) Patent Application Publication
(10) Pub. No.: US 2004/0164673 A1
(43) Pub. Date: Aug. 26, 2004

(54) Organic electro luminescence display panel and method for manufacturing the same

(75) Inventors: Harumi Suzuki, Kariya-city (JP); Masaaki Ozaki, Kariya-city (JP); Kojiro Tachi, Nagoya-city (JP); Kazushige Kojima, Aichi-gun (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/779,799

(22) Filed: Feb. 18, 2004

(30) Foreign Application Priority Data
Feb. 24, 2003 (JP) 2003-45982
Dec. 10, 2003 (JP) 2003-412063

(51) Int. Cl. H05B 33/00

(52) U.S. Cl. 313/506

(57) ABSTRACT

An organic electro luminescence display panel includes a hole transport layer and a luminescent layer disposed on the hole transport layer. The luminescent layer includes at least first and second luminescent layers. The first and second luminescent layers are repeatedly arranged on the hole transport layer so as to be adjacent each other. The first luminescent layer includes a first dopant for emitting a first light having a first wavelength, and the second luminescent layer includes a second dopant for emitting a second light having a second wavelength, which is shorter than the first wavelength. No first dopant is disposed between the hole transport layer and the second luminescent layer.

### CROSS REFERENCE TO RELATED APPLICATIONS

This application is based on Japanese Patent Applications No. 2003-45982 filed on Feb. 24, 2003 and No. 2003-412063 filed on Dec. 10, 2003, the disclosures of which are incorporated herein by reference.

### FIELD OF THE INVENTION

The present invention relates to an organic electro luminescence display panel and a method for manufacturing the same.

### BACKGROUND OF THE INVENTION

An organic electro luminescence (i.e., EL) device is a self-luminous device, i.e., the device emits light by itself. Therefore, the device has an excellent visibility. Further, the device is driven with a low voltage, i.e., the device can be activated with the low voltage, for example, between several of volts and several tens of volts. Therefore, the device having a drive circuit can be trimmed weight. Thus, the device has an excellent visibility and a lightweight.

An organic EL display panel having the organic EL device according to a prior art includes multiple luminescent layers having different luminescent colors of light. The luminescent layers are repeatedly arranged on the same plane. Specifically, the luminescent layers are disposed repeatedly with a planar arrangement. Thus, the panel can emit lights having multiple colors, i.e., emit lights having different wavelengths, so that the panel provides a multi-color EL display panel. This type of panel is defined as a multiple-luminescent-layer planer-arrangement display panel (i.e., a multi-layer planer-type display panel).

This multi-layer planer-type display panel includes at least an anode layer, a hole transport layer, an emitter layer (i.e., a luminescent layer), an electron transport layer, and a cathode layer, which are disposed and stacked on a substrate in this order. The luminescent layer includes multiple single-light (i.e., single-color) luminescent layers having a different color (i.e., having a different wavelength). Each single-color luminescent layer is deposited separately on a substrate so that the single-color luminescent layer is stacked and repeatedly arranged on the plane (i.e., on the substrate). For example, the luminescent layer has three different single-color luminescent layers so that the panel provides a full-color display panel. Specifically, the single-color luminescent layers are red, green and blue light luminescent layers (i.e., RGB light luminescent layers) stacked and arranged on the plane. Here, the red light luminescent layer emits a red (i.e., R) light, the green light luminescent layer emits a green (i.e., G) light, and the blue light luminescent layer emits a blue (i.e., B) light.

A method for manufacturing the above multi-layer planer-type display panel is provided with using multiple masks having a different opening corresponding to the single-color luminescent layer. One depositing material is deposited on a substrate in order with using the mask so that the single-color luminescent layer is deposited. Then, other depositing materials are deposited on the substrate with using other masks so that other single-color luminescent layers are deposited. Thus, the multi-layer planer-type display panel is formed. However, a clearance is usually formed between the mask and the substrate, so that the depositing material penetrates from the opening of the mask to the underside of the mask. That is, the depositing material is deposited beneath the mask.

In a case where the degree of the penetration of the depositing material becomes large so that the depositing material is deposited on the underside of the mask more than a predetermined amount, and deposited on other area of a predetermined area, the depositing material is mixed into another luminescent layer, which is to be deposited later. Specifically, the depositing material penetrates into the neighbor luminescent layer, in which the depositing material is deposited. Therefore, the color purity of the neighbor luminescent layer contaminated with the depositing material is decreased. Here, the color purity is defined with the luminescent color of the light emitted by the neighbor luminescent layer.

In view of the above problem, a method for manufacturing the multi-layer planar-type display panel is disclosed in Japanese Patent Application Publication No. H10-41069. In the method, a distance between a mask and a substrate becomes small with using a magnet, so that it prevents a depositing material from penetrating into a neighbor luminescent layer. However, the mask cannot contact the substrate completely, i.e., the distance cannot become zero. That is because an organic film such as a luminescent layer on the substrate is protected from damaging with the mask so that a fault of display panel is caused. Therefore, the distance between the mask and the substrate is set to be larger than several micrometers. Thus, the depositing material cannot be prevented from penetrating into the clearance completely.

Another method for manufacturing the multi-layer planar-type display panel is disclosed in Japanese Patent Application Publication No. 2000-227771 (i.e., U.S. Pat. No. 6,433,486-B1). In the method, a margin in a horizontal direction is secured to become larger than a penetration width, in which a depositing material penetrates. Therefore, a distance between one single-color luminescent layer and neighboring single-color luminescent layer becomes large, so that the depositing material does not penetrate into the neighboring single-color luminescent layer. In this case, it is easy to remove the penetration area from a picture element (i.e., pixel) area. However, an area that does not emit the light becomes larger, so that the opening area on the whole panel becomes small. If the panel having such a small opening area is required to maintain brightness, a luminescent brightness of each pixel is necessitated to become higher. Thus, endurance of the pixel is reduced. Specifically, the brightness of the pixel is deteriorated (i.e., is reduced) rapidly.

Further, other methods for manufacturing a multi-layer planar-type display panel are disclosed in Japanese Patent Application Publications No. 2001-23772 and No. H11-214157 (i.e., U.S. Pat. No. 6,366,016-B1). In these methods, each luminescent layer and each electron transport layer corresponding to a single-color luminescent layer are separately deposited. In this case, each luminescent layer is deposited in an order from a long wavelength light luminescent layer to a short wavelength light luminescent layer. That is, the red, green and blue light luminescent layers are deposited in this order. Therefore, a dopant of the long wavelength light luminescent layer penetrates between the short wavelength light luminescent layer and the hole transport layer. Thus, the dopant of the long wavelength light luminescent layer is disposed around an interface between the hole transport layer and the short wavelength light luminescent layer. Specifically, the interface provides a main luminous region of the short wavelength light. Thus, the color purity of the light emitted at the short wavelength light luminescent layer is reduced. In these methods, it is difficult to improve the reduction of the color purity of the light of the short wavelength light luminescent layer.

### SUMMARY OF THE INVENTION

In view of the above problem, it is an object of the present invention to provide an organic electro luminescence display panel having high color purity. Specifically, in case of manufacturing the display panel, a dopant of a long wavelength light luminescent layer is prevented from penetrating between a short wavelength light luminescent layer and a charge transport layer (i.e., an electron or hole transport layer) so that the display panel is limited from decreasing the color purity.

It is another object of the present invention to provide an organic electro luminescence display panel having high luminous efficiency. Specifically, in case of manufacturing the display panel, even if a host material of one single-color luminescent layer adheres to an interface between another single-color luminescent layer and a hole transport layer, the display panel is limited from decreasing the luminous efficiency. Here, the one single-color luminescent layer is adjacent to the other single-color luminescent layer, and the one and the other single-color luminescent layers emit different lights having different color, respectively.

It is further another object of the present invention to provide a method for manufacturing an organic electro luminescence display panel having high luminous efficiency and/or high luminous efficiency.

An organic electro luminescence display panel includes a hole transport layer and a luminescent layer disposed on the hole transport layer. The luminescent layer includes at least first and second luminescent layers. The first and second luminescent layers are repeatedly arranged on the hole transport layer so as to be adjacent each other. The first luminescent layer includes a first dopant for emitting a first light having a first wavelength, and the second luminescent layer includes a second dopant for emitting a second light having a second wavelength, which is shorter than the first wavelength. No first dopant is disposed between the hole transport layer and the second luminescent layer.

The above display panel is limited from decreasing the color purity so that the display panel has high color purity.

Preferably, the display panel further includes a substrate, an anode layer, an electron transport layer and a cathode layer. The anode layer, the hole transport layer, the luminescent layer, the electron transport layer and the cathode layer are disposed on the substrate in this order.

Preferably, the hole transport layer includes a plurality of parts of the hole transport layer. More preferably, the parts of the hole transport layer include at least first and second part hole transport layers, which correspond to the first and second luminescent layers. Both of the first luminescent layer and the first part hole transport layer are formed independently from the second luminescent layer and the second part hole transport layer. Furthermore preferably, one of the first and second luminescent layers and one part of the hole transport layer corresponding to the one of the first and second luminescent layers are successively formed so that no dopant of the other one of the first and second luminescent layers is disposed between the one part of the hole transport layer and the one of the first and second luminescent layers.

Preferably, the luminescent layer further includes a third luminescent layer, which includes a third dopant for emitting a third light having a third wavelength. The first light is a red light, the second light is a green light, and the third light is a blue light. The first, second and third luminescent layers are repeatedly arranged on the hole transport layer so as to be adjacent together.

Preferably, no first dopant is disposed between the electron transport layer and the second luminescent layer. More preferably, the electron transport layer includes a plurality of parts of the electron transport layer. Furthermore preferably, the parts of the electron transport layer include at least first and second part electron transport layers, which correspond to the first and second luminescent layers. Both of the first luminescent layer and the first part electron transport layer are formed independently from the second luminescent layer and the second electron transport layer.

Further, an organic electro luminescence display panel includes a hole transport layer and a luminescent layer disposed on the hole transport layer. The luminescent layer includes at least first and second luminescent layers. The first and second luminescent layers are repeatedly arranged on the hole transport layer so as to be adjacent each other. At least one of the first and second layers includes a hole transporting material as a host material.

The above display panel has high luminous efficiency.

Preferably, the display panel further includes a substrate, an anode layer, an electron transport layer and a cathode layer. The anode layer, the hole transport layer, the luminescent layer, the electron transport layer and the cathode layer are disposed on the substrate in this order. The first luminescent layer includes a first dopant for emitting a first light having a first wavelength, and the second luminescent layer includes a second dopant for emitting a second light having a second wavelength, which is shorter than the first wavelength. More preferably, the luminescent layer further includes a third luminescent layer, which includes a third dopant for emitting a third light having a third wavelength. The first light is a red light, the second light is a green light, and the third light is a blue light. The first, second and third luminescent layers are repeatedly arranged on the hole transport layer so as to be adjacent together.

Furthermore, a method for manufacturing an organic electro luminescence display panel is provided. The display panel includes a hole transport layer and a luminescent layer disposed on the hole transport layer. The luminescent layer includes at least first and second luminescent layers, which are repeatedly arranged on the hole transport layer so as to be adjacent each other. One of the first and second layers includes a hole transporting material as a host material. The method includes the step of: forming the one of the first and second luminescent layers on the hole transport layer; and forming the other one of the first and second luminescent layers on the hole transport layer after the step of forming the one of the first and second luminescent layers.

The display panel manufactured with the above method has high luminous efficiency.

Furthermore, a method for manufacturing an organic electro luminescence display panel is provided. The display panel includes a hole transport layer and a luminescent layer disposed on the hole transport layer. The luminescent layer includes at least first and second luminescent layers, which are repeatedly arranged on the hole transport layer so as to be adjacent each other. The hole transport layer includes at least first and second part hole transport layers, which correspond to the first and second luminescent layers. The method includes the step of: forming one of the first and second part hole transport layers; forming one of the first and second luminescent layers on the one of the first and second part hole transport layers; forming the other one of the first and second part hole transport layers; and forming the other one of the first and second luminescent layers on the other one of the first and second part hole transport layers.

The display panel manufactured with the above method has high color purity.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic cross-sectional view showing a multi-layer planar-type display panel according to a first embodiment of the present invention;

FIGS. 2A and 2B are cross-sectional views explaining a method for manufacturing a display panel, according to the first embodiment;

FIGS. 3A and 3B are cross-sectional views explaining a method for manufacturing a display panel, according to the first embodiment;

FIGS. 4A to 4C are cross-sectional views explaining a method for manufacturing a display panel, according to the first embodiment;

FIGS. 5A to 5C are cross-sectional views explaining a method for manufacturing a display panel, according to the first embodiment;

FIG. 6 is a schematic cross-sectional view showing a multi-layer planar-type display panel according to a second embodiment of the present invention;

FIGS. 7A and 7B are cross-sectional views explaining a method for manufacturing a display panel, according to the second embodiment;

FIGS. 8A and 8B are cross-sectional views explaining a method for manufacturing a display panel, according to the second embodiment;

FIGS. 9A to 9C are cross-sectional views explaining a method for manufacturing a display panel, according to the second embodiment;

FIGS. 10A to 10C are cross-sectional views explaining a method for manufacturing a display panel, according to the second embodiment;

FIG. 11 is a schematic cross-sectional view showing a multi-layer planar-type display panel according to a third embodiment of the present invention;

FIG. 12 is a schematic cross-sectional view showing a multi-layer planar-type display panel according to a fourth embodiment of the present invention;

FIGS. 13A and 13B are cross-sectional views explaining a method for manufacturing a display panel, according to the fourth embodiment;

FIGS. 14A to 14C are cross-sectional views explaining a method for manufacturing a display panel, according to the fourth embodiment;

FIG. 15 is a schematic cross-sectional view showing a multi-layer planar-type display panel according to a fifth embodiment of the present invention;

FIG. 16 is a schematic cross-sectional view showing a multi-layer planar-type display panel according to a preliminary try of the present invention; and

FIG. 17 is a schematic cross-sectional view showing a multi-layer planar-type display panel according to another preliminary try of the present invention.

### DETAILED DESCRIPTION OF THE PREFERRED EMBODIMENTS

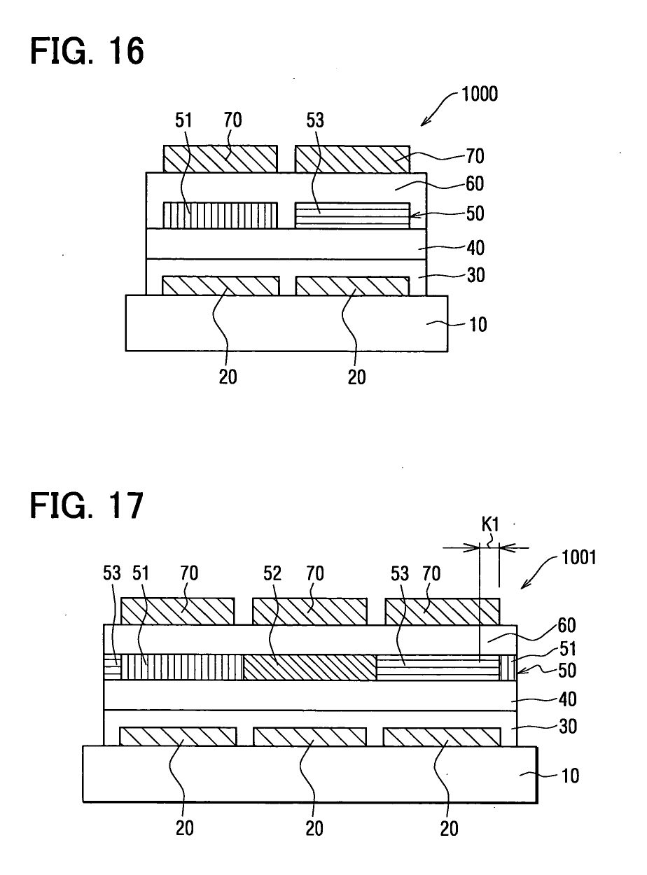

Preliminarily, the inventors have studied the problem about a penetration of a depositing material into a different single-color luminescent layer. FIG. 16 shows a multi-layer planar-type display panel 1000 having two single-color luminescent layers 51, 53. Two single-color luminescent layers 51, 53 emit two different colors, respectively, and disposed periodically on the same plane. The display panel 1000 includes a substrate 10 made of glass and the like, an anode layer 20, a hole injection layer 30, a hole transport layer 40, the single-color luminescent layers 51, 53, an electron transport layer 60 and a cathode layer 70, which are stacked and disposed in this order. Two single-color luminescent layers 51, 53 are a red light luminescent layer 51 and a blue light luminescent layer 53, which composes a luminescent layer 50. Two single-color luminescent layers 51, 53 are separately deposited on the hole transport layer 40, and disposed on the same plane (i.e., on the hole transport layer 40) repeatedly, i.e., arranged repeatedly on the same plane.

The display panel 1000 is formed as follows. The anode layer 20, the hole injection layer 30 and the hole transport layer 40 are formed (i.e., deposited) on the substrate 10 in this order. Then, each of the red and blue light luminescent layers 51, 53 is selectively deposited on the hole transport layer 40 with using a mask, respectively. After that, the electron transport layer 60 and the cathode layer 70 are deposited in this order, respectively.

Here, there are two ways of forming two single-color luminescent layers 51, 53. One way is such that the red light luminescent layer 51 is formed at first and then the blue light luminescent layer 53 is formed. The blue light luminescent layer 53 is formed such that the mask is displaced with a predetermined distance. Here, the red light luminescent layer 51 works as a long wavelength light luminescent layer for emitting a longer wavelength light (i.e., a red light), and the blue light luminescent layer 53 works as a shorter wavelength light luminescent layer for emitting a short wavelength light (i.e., a blue light).

In this case, a host material (i.e., a matrix material) and a dopant of the red light luminescent layer 51 penetrate into a blue-light-luminescent-layer-to-be-formed region on the hole transport layer 40. The blue-light-luminescent-layer-to-be-formed region is next to the red light luminescent layer 51. After that, the blue light luminescent layer 53 is formed on the blue-light-luminescent-layer-to-be-formed region, which is disposed on the hole transport layer 40 and includes the host material and dopant of the red light luminescent layer 51. Therefore, the dopant of the red light luminescent layer 51 is disposed between the blue light luminescent layer 53 and the hole transport layer 40, so that the dopant of the red light luminescent layer 51 is introduced into an interface between the blue light luminescent layer 53 and the hole transport layer 40.

Each dopant defines a color of light emitted from the single-color luminescent layer 51, 53. The energy gap of the dopant of the red light luminescent layer 51 in the matrix material is smaller than that of another dopant of the blue light luminescent layer 53 in another matrix material. That is because the red light luminescent layer 51 emits the shorter wavelength light (i.e., the red light), compared with the blue light luminescent layer 53. Therefore, the red light luminescent layer 51 emits the red light with a comparatively small energy, which is smaller than that of the blue light luminescent layer 53. Therefore, the penetrated dopant of the red light luminescent layer 51 penetrated into the interface between the blue light luminescent layer 53 and the hole transport layer 40 emits the red light easily rather than the other dopant of the blue light luminescent layer 53. Thus, part of the blue light luminescent layer, in which the dopant of the red light luminescent layer 51 penetrates, emits a mixed light mixed with the red and blue light. Thus, the color purity of the blue light luminescent layer 53 is reduced.

On the other hand, the other way is such that the blue light luminescent layer 53 is formed at first and then the red light luminescent layer 51 is formed. In this case, when the red light luminescent layer 51 is formed after the blue light luminescent layer 53 is formed, the host material and the dopant of the red light luminescent layer 51 penetrate between the mask and the blue light luminescent layer 53, which is next to the red light luminescent layer 51. After that, the electron transport layer 60 is formed on the red and blue light luminescent layers 51, 53. Thus, the dopant of the red light luminescent layer 51 is formed between the blue light luminescent layer 53 and the electron transport layer 60, so that the dopant is introduced into an interface between the blue light luminescent layer 53 and the electron transport layer 60.

The penetrated dopant of the red light luminescent layer 51 penetrated into the interface between the blue light luminescent layer 53 and the electron transport layer 60 emits the red light easily rather than the other dopant of the blue light luminescent layer 53. Thus, part of the blue light luminescent layer, in which the dopant of the red light luminescent layer 51 penetrates, emits a mixed light mixed with the red and blue light. Thus, the color purity of the blue light luminescent layer 53 is reduced.

As a result, the above method provides a reduction of the color purity of the blue light luminescent layer 53 because the dopant of the red light luminescent layer 51 penetrates into the interface between the blue light luminescent layer 53 and the hole transport layer 40 or the electron transport layer 60.

Further, the inventors have studied another method for manufacturing another multi-layer planar-type display panel 1001 having the red light luminescent layer 51, a green light luminescent layer 53 and the blue light luminescent layer 53. FIG. 17 shows the multi-layer planar-typed is play panel 1001. Three single-color luminescent layers 51-53 emit three different colors, respectively, and disposed periodically on the same plane.

The luminescent layer 50 of the display panel 1001 is formed as follows. The luminescent layer 50 is formed such that each single-color luminescent layer 51-53 is deposited in an order from a long wavelength light luminescent layer to a short wavelength light luminescent layer. That is, the red, green and blue light luminescent layers are deposited in this order. Specifically, the red light luminescent layer 51 is formed at first, and then the green light luminescent layer 52 is formed. At last, the blue light luminescent layer 53 is formed. Thus, the display panel 1001 is completed. In this case, the dopant of the red light luminescent layer 51 contaminates in a part of the blue light luminescent layer 53, which is next to the red light luminescent layer 51, for example, shown as an area K1 in FIG. 17. Therefore, the color purity of the light emitted at the part of the blue light luminescent layer 53 such as the area K1 is reduced.

Specifically, the chromaticity coordinate of the light emitted at the whole blue light luminescent layer 53 including the part, in which the dopant of the red light luminescent layer 51 penetrates, is (0.19, 0.19). That is albescent blue light, i.e., a whitish blue light. Here, the chromaticity coordinate is determined by the international commission on illumination in 1931 (i.e., CIE1931). On the other hand, the chromaticity coordinate of the other part of the blue light luminescent layer 53, in which the dopant of the red light luminescent layer 51 does not penetrate, is (0.16, 0.14). That shows the pure blue light.

Furthermore, the inventors have studied about the problem of the penetration of the depositing material. In general, the host material of the luminescent layer is mainly composed of an electron transport material. For example, in the display panel 1000 shown in FIG. 16, in a case where the red light luminescent layer 51 is firstly deposited, the electron transport material of the red light luminescent layer 51 as the host material penetrates to the upper surface of the hole transport layer 40, which is disposed on the blue-light-luminescent-layer-to-be-formed region, and disposed next to the red light luminescent layer 51. After that, the blue light luminescent layer 53 is formed on that upper surface, so that the electron transport material of the red light luminescent layer 51 is inserted between the hole transport layer 40 and the blue light luminescent layer 53.

In this case, a hole to be introduced from the hole transport layer 40 to the blue light luminescent layer 53 is recombined with an electron delivered from the electron transport material, so that the hole is not sufficiently supplied to the blue light luminescent layer 53. Thus, the luminous efficiency of the blue light luminescent layer 53 is reduced.

The above reduction of the luminous efficiency is also occurred in a case where the blue light luminescent layer 53 is deposited firstly. In this case, the electron transport material of the blue light luminescent layer 53 as the host material penetrates between the red light luminescent layer 51 and the hole transport layer 40, so that the luminous efficiency of the red light luminescent layer 51 is reduced.

Thus, the problem about the reduction of the luminous efficiency caused by the penetration of the host material is always occurred whether the red light luminescent layer 51 is firstly deposited or not. Specifically, the problem does not depend on a deposition order of the single-color luminescent layer, and is derived from a well-known art that the host material of the single-color luminescent layer in the organic EL display panel is made of the electron transport material.

(First Embodiment)

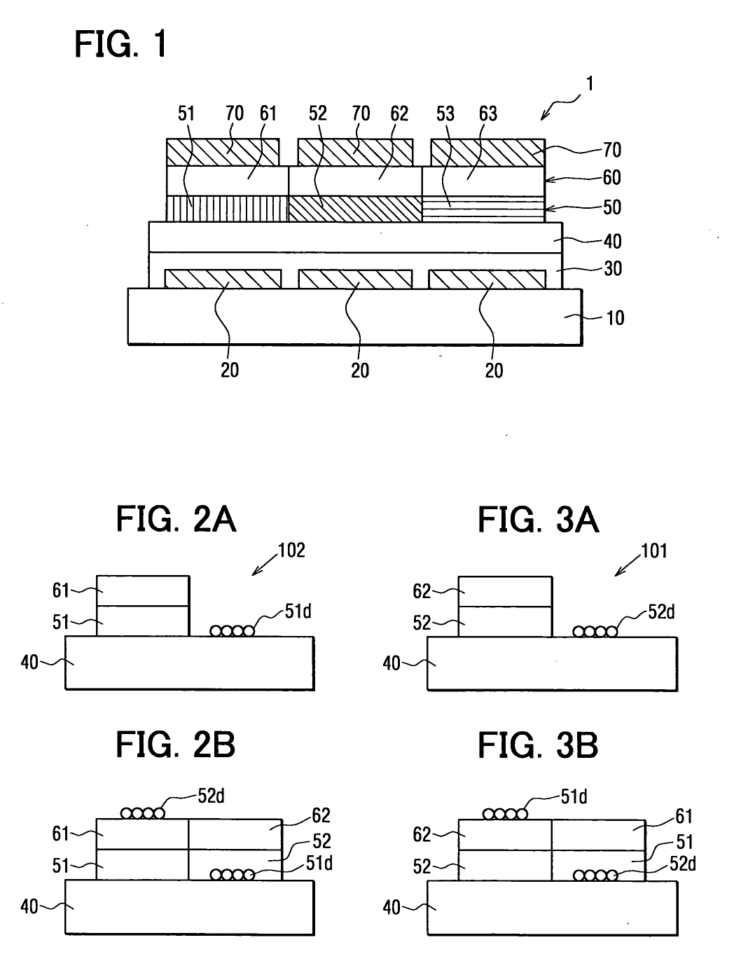

An organic electro luminescence display panel (i.e., an organic EL display panel) as a multiple-luminescent-layer planer-arrangement display panel (i.e., a multi-layer planer-type display panel) 1 according to a first embodiment of the present invention is shown in FIG. 1. The organic EL display panel 1 includes a substrate 10, an anode layer 20, a hole injection layer 30, a hole transport layer 40, a luminescent layer 50, an electron transport layer 60 and a cathode layer 70, which are stacked in this order. The luminescent layer 50 includes multiple single-color luminescent layers 51-53 for emitting different lights having different colors, which are repeatedly arranged on a plane.

In this embodiment, a method for manufacturing the organic EL display panel 1 is such that each single-color luminescent layer 51-53 and at least part of the electron transport layer 60 corresponding to the single-color luminescent layer 51-53 are deposited successively and independently from other single-color luminescent layers 51-53 so that they are deposited on a predetermined area (i.e., a pixel area) corresponding to the single-color luminescent layer 51-53. Further, more than two layers including the single-color luminescent layer 51-53 and part of the electron transport layer 60 corresponding to the single-color luminescent layer 51-53 are deposited successively, independently and separately on the predetermined area of each single-color luminescent layer 51-53.

The luminescent layer 50 is composed of a red light luminescent layer 51 for emitting a red light, a green light luminescent layer 52 for emitting a green light and a blue light luminescent layer 53 for emitting a blue light as three single-color luminescent layers 51-53, so that the luminescent layer emits three different colors of light. Thus, each single-color luminescent layer 51-53 emits a different light having a different wavelength corresponding to the red (i.e., R), green (i.e., G) or blue (i.e., B) light. Thus, each pixel area for emitting the light corresponding to the red, green or blue light is arranged repeatedly on the plane, so that each single-color luminescent layer 51-53 is disposed repeatedly on the plane (i.e., on the hole transport layer 40).

The electron transport layer 60 is separated into three parts, which correspond to three single-color luminescent layers 51-53, respectively. Specifically, one part of the electron transport layer 60 and the single-color luminescent layer 51-53 is separately and independently deposited so that the pixel area corresponding to the single-color luminescent layer 51-53 is formed. Here, each part of the electron transport layer 61-63 corresponds to the single-color luminescent layer 51-53, i.e., the red, green or blue light luminescent layer 51-53, so that the electron transport layer 60 is composed of three parts 61-63, i.e., a red, green and blue part electron transport layers 61-63.

The substrate 10 is made of electrically insulation material such as glass and resin having transparent property. In this embodiment, the substrate 10 is made of glass. The anode layer 20 formed on the substrate 10 is made of transparent conductive film such as an indium-tin-oxide film (i.e., ITO film) and an indium-zinc-oxide film. The film thickness of the anode layer 20 is, for example, in a range between 100 nm and 1 μm. In this embodiment, the anode layer 20 is made of the ITO film having the film thickness of 50 nm.

The hole injection layer 30 is formed on the anode layer 20, and is made of a hole injecting material, which provides a hole and is useable for the organic EL display panel. In this embodiment, the hole injection layer 30 is made of copper phthalocyanin film (i.e., CuPc film), and has the film thickness of 10 nm.

The hole transport layer 40 is formed on the hole injection layer 30, and is made of a hole transporting material, which transports the hole and is useable for the organic EL display panel. In this embodiment, the hole transport layer 40 is made of alpha naphthyl phenyl benzene film (i.e., α-NPD film), and has the film thickness of 40 nm.

The luminescent layer 50 is formed on the hole transport layer 40, and is made of a luminous material, which is useable for the organic EL display panel. Specifically, the luminescent layer 50 is formed of a host material (i.e., a matrix material) and a various dopant. Mainly, the color of the light emitted at the luminescent layer depends on the dopant. In this embodiment, the red light luminescent layer 51 is made of tris(8-hydrooxyquinoline)aluminum (i.e., Alq3) as a host material and [4-(dicyanomethylene)-2-methyl-6-(p-dimethylaminostyryl)-4H-pyran] (i.e., DCM1) as adopant, i.e., a fluorescent dye. Specifically, the DCM1 is doped (i.e., added) in the Alq3 with lwt %. The film thickness of the red light luminescent layer 51 is about 40 nm. The green light luminescent layer 52 is made of the Alq3 as a host material and Quinacridone as a dopant. Specifically, the Quinacridone is doped in the Alq3 with 1 wt %. The film thickness of the green light luminescent layer 52 is about 40 nm. The blue light luminescent layer 53 is made of bis(2-methyl-8quinolinolate)(para-phenylphenolate)aluminum(III) (i.e., BAlq) as a host material and Perylene as a dopant. Specifically, the Perylene is doped in the BAlq with 1 wt %. The film thickness of the blue light luminescent layer 53 is about 40 nm.

The red, green and blue part electron transport layers 61-63 correspond to the red, green and blue light luminescent layers 51-53, and are separately formed on the red, green and blue light luminescent layers 51-53, respectively. Each of the red, green and blue part electron transport layers 61-63, i.e., the electron transport layer 60 is made of an electron transporting material, which is useable for the organic EL display panel. In this embodiment, each of the red, green and blue part electron transport layers 61-63 is made of the Alq3, and has the film thickness of 20 nm.

The cathode layer 70 is formed on the electron transport layer 60, and is made of a cathode material, which is useable for the organic EL display panel. In this embodiment, the cathode layer 70 is made of Lithium fluoride (i.e., LiF) and aluminum (i.e., Al). Specifically, the LiF film having the film thickness of 0.5 nm is formed on the electron transport layer 60, and then the Al film having the film thickness of 90 nm is formed on the LiF film, so that the cathode layer 70 is made of a multi-layer film (i.e., a stacked film).

In the above multi-layer planar-type display panel 1, i.e., the organic EL display panel 1, one picture element (i.e., pixel) is provided by a region between the anode layer 20 and the cathode layer 70. Specifically, each of the red, green and blue light luminescent layers 51-53 corresponds to one pixel. When a predetermined voltage is applied to the pixel, i.e., the voltage is applied between the anode layer 20 and the cathode layer 70, the single-color luminescent layer 51-53 corresponding to the pixel emits the light. In this case, each pixel includes one of red, green and blue pixels, which emit the red, green and blue lights, respectively. Specifically, the red pixel emits the red light, the green pixel the green light and the blue pixel the blue light. Each pixel can be controlled so as to emit or not to emit the light, so that the display panel 1 provides a multi-color display. Specifically, the display panel 1 displays the red color, green color, blue color, and their mixed color.

The organic EL display panel 1 is manufactured as follows. Each of the red, green and blue light luminescent layers 51-53 and the red, green or blue part electron transport layer 61-63 corresponding the single-color luminescent layer are formed sequentially so that the red, green or blue pixel is formed.

At first, an indium tin oxide film (i.e., an ITO film) is formed on the substrate 10 with using a spattering method. Then, the ITO film is patterned into a predetermined pattern with using a photolithography method, so that the anode layer 20 is formed. Then, the CuPc film as the hole injection layer 30 is formed on the anode layer 20 with the film thickness of 10 nm with using a vapor deposition method. Then, the NPD film as the hole transport layer 40 is formed on the CuPc film with the film thickness of 40 nm.

Then, a mask is prepared. The mask is used for forming an organic film only on a selective area, which is preliminarily determined and corresponds to one of the red, green and blue light luminescent layers 51-53 (i.e., the selective area corresponds to one of the red, green and blue pixels). One of the red, green and blue light luminescent layers 51-53 is formed on a predetermined area with using the mask. Then, one of the red, green or blue part electron transport layers 61-63 corresponding to the formed single-color luminescent layer 51-53 is formed on the single-color luminescent layer 51-53. Subsequently, another single-color luminescent layer 51-53 is formed on another predetermined area with using the mask. Then, another one of the red, green or blue part electron transport layers 61-63 corresponding to the other single-color luminescent layer 51-53 is formed on the other predetermined area. Finally, the last one of the single-color luminescent layers 51-53 is formed on a rest area with using the mask, so that the whole luminescent layer 50 is formed. Then, the last one of the red, green or blue part electron transport layers 61-63 corresponding to the last single-color luminescent layer 51-53 is formed, so that the whole electron transport layer 60 is formed.

Thus, both of the single-color luminescent layer 51-53 and one of the red, green and blue part electron transport layers 61-63 corresponding to the single-color luminescent layer 51-53 are formed successively, and separately and independently from other single-color luminescent layers 51-53. That is, the single-color luminescent layer 51-53 and its corresponding part electron transport layer 61-63 are formed with using a time-sharing method. Specifically, the mask is made of glass or metal such as stainless steel having an opening corresponding to the single-color luminescent layer 51-53. The single-color luminescent layer 51-53 and the electron transport layer 60 are formed with using the vapor deposition method.

In this embodiment, the single-color luminescent layers 51-53 are formed in an order from the shortest wavelength light luminescent layer such as the blue light luminescent layer 53 to the longest wavelength light luminescent layer such as the red light luminescent layer 51, i.e., the blue, green and red light luminescent layers 51-53 are formed in this order. Specifically, the method for forming the luminescent layer 50 and the electron transport layer 60 is described in detail as follows.

At first, the mask is positioned on the substrate 10 so that the opening of the mask is disposed on a blue-pixcel-to-be-formed region (i.e., the blue-light-luminescent-layer-to-be-formed region). Then, the BAlq film is deposited with using the vapor deposition method with the film thickness of 40 nm. Then, the Perylene is doped with 1 wt % into the BAlq film, so that the blue light luminescent layer 53 is formed. Then, the Alq3 film is formed on the blue light luminescent layer 53 with the film thickness of 20 nm, so that the blue part electron transport layer 63 is formed. Thus, the blue pixel is formed.

Next, the mask is displaced at a predetermined position so that the opening of the mask is disposed on a green-pixcel-to-be-formed region (i.e., the green-light-luminescent-layer-to-be-formed region). Then, the Alq3 film is deposited with using the vapor deposition method with the film thickness of 40 nm. Then, the Quinacridone is doped with 1 wt % into the Alq3 film, so that the green light luminescent layer 52 is formed. Then, the Alq3 film is formed on the green light luminescent layer 52 with the film thickness of 20 nm, so that the green part electron transport layer 62 is formed. Thus, the green pixel is formed.

At last, the mask is displaced at another predetermined position so that the opening of the mask is disposed on a red-pixcel-to-be-formed region (i.e., the red-light-luminescent-layer-to-be-formed region). Then, the Alq3 film is deposited with using the vapor deposition method with the film thickness of 40 nm. Then, the DCM1 is doped with 1 wt % into the Alq3 film, so that the red light luminescent layer 51 is formed. Then, the Alq3 film is formed on the red light luminescent layer 51 with the film thickness of 20 nm, so that the red part electron transport layer 61 is formed. Thus, the red pixel is formed.

After that, the LiF film having the film thickness of 0.5 nm and the Al film having the film thickness of 90 nm are formed successionally on the electron transport layer 60, so that the cathode layer 70 is formed. Thus, the organic EL display panel 1 is completed.

In the above method, the luminescent layer 50 and the electron transport layer 60 are formed such that each pixel is separately and independently deposited. Therefore, in each of the red, green or blue-pixel-to-be-formed region, both of the single-color luminescent layer 51-53 and the red, green or blue part electron transport layer 61-63 corresponding to the single-color luminescent layer 51-53 are successively formed. Thus, the single-color luminescent layer 51-53 and the red, green or blue electron transport layer 61-63 contact each other. That is because the electron transport layer 60 is separated into multiple parts, i.e., three parts (i.e., the red, green blue part electron transport layers) 61-63 corresponding to the single-color luminescent layer, i.e., the red, green or blue light luminescent layer 51-53.

Each of the red, green or blue part electron transport layers 61-63 is formed on the single-color luminescent layer 51-53 successively, so that the dopant of the red light luminescent layer 51 as the longest wavelength light luminescent layer does not penetrate between the shorter wavelength light luminescent layer 52, 53 and its corresponding part electron transport layer 62, 63, which is next to the longest wavelength light luminescent layer 51. Specifically, the DCM1 as the dpoant of the red light luminescent layer 51 does not penetrate between the green light luminescent layer 52 and the green part electron transport layer 62 nor between the blue light luminescent layer 53 and the blue part electron transport layer 63, which are next to the red light luminescent layer 51.

Further, in the above method, the shortest wavelength light luminescent layer 53 and its corresponding part electron transport layer 63 is firstly formed, and then the longer wavelength light luminescent layer 51, 52 and its corresponding part electron transport layer 61, 62 are formed. Specifically, the blue light luminescent layer 53 and the blue part electron transport layer 63, the green light luminescent layer 52 and the green part electron transport layer 62, and the red light luminescent layer 51 and the red part electron transport layer 61 are formed in this order.

Thus, the green and blue light luminescent layers 52, 53 are formed on the hole transport layer 40 before the red light luminescent layer 51 is formed on the hole transport layer 40, so that the dopant (i.e., the DCM1) of the longest wavelength light luminescent layer 51 does not penetrate between the shorter wavelength light luminescent layer 52, 53 and the hole transport layer 40.

This method is preferable method for manufacturing the display panel 1 in a case where the host material of the luminescent layer 60 is formed of the electron transporting material. The art that the host material is the electron transporting material is well-known and commonly utilized. In general, the host material of the luminescent layer 50 has the electron transporting property so that a luminous region in the luminescent layer 50 is mainly disposed around an interface between the hole transport layer 40 and the luminescent layer 50. Here, at the luminous region, a charge is recombined so as to emit the light. The electron derived from the luminescent layer 50 is recombined with the hole delivered from the hole transport layer 40 at the interface. Thus, the main luminous region of the luminescent layer 50 is disposed around the interface between the hole transport layer 40 and the luminescent layer 50.

If the longest wavelength light luminescent layer 51 and its corresponding part electron transport layer 61 are firstly formed, and then the shorter wavelength light luminescent layer 52, 53 and its corresponding part electron transport layer 62, 63 are formed, the dopant of the longest wavelength light luminescent layer 51 may penetrate on the hole transport layer 40 that is disposed on the shorter-wavelength-light-luminescent-to-be-formed region (i.e., the green- or blue-light-luminescent-layer-to-be-formed region). Specifically, if the red light luminescent layer 51 and the red part electron transport layer 61 are formed before the green or blue light luminescent layer 52, 53 and the green or blue part electron transport layer 62, 63 are formed, the DCM1 of the red light luminescent layer 51 may penetrate on the hole transport layer 40 that is disposed on the green- or blue-light-luminescent-layer-to-be-formed region although the DCM1 does not penetrate between the green or blue light luminescent layer 52, 53 and the green or blue part electron transport layer 62, 63. In this case, the DCM1 of the red light luminescent layer 51 is disposed around the interface between the hole transport layer 40 and the green or blue light luminescent layer 52, 53. Here, the interface is the main luminous region of the green or blue light luminescent layer 52, 53. Therefore, the light emitted from the green or blue light luminescent layer 52, 53 has a mixed color, so that the color purity of the light emitted from the green or blue light luminescent layer 52, 53 is reduced.

Thus, in the first embodiment, the electron transport layer 60 works as a charge transport layer, and each part of the electron transport layer 61-63 is formed independently and separately. Further, the single-color luminescent layers 51-53 are formed in the order from the shortest wavelength light luminescent layer 53 to the longest wavelength light luminescent layer 51. Therefore, the dopant of the longest wavelength light luminescent layer 51 is prevented from penetrating between the shorter wavelength light luminescent layer 52, 53 and its corresponding part electron transport layer 62, 63. Further, the dopant of the longest wavelength light luminescent layer 51 is prevented from penetrating between the shorter wavelength light luminescent layer 52, 53 and the hole transport layer 40. Therefore, the color purity of each pixel (i.e., each single-color luminescent layer 51-53) is protected from decreasing. Thus, in case of manufacturing the display panel 1, the dopant of the longest wavelength light luminescent layer 51 is prevented from penetrating between the shorter wavelength light luminescent layer 52, 53 and the charge transport layer (i.e., the electron or hole transport layer) 40, 62, 63 so that the display panel 1 is limited from decreasing the color purity. The display panel 1 provides a RGB multi-color luminescence display panel without mixing color, which has high color purity.

The effect of the method for manufacturing the display panel 1 according to the first embodiment is described as follows. FIGS. 2A and 2B explain a comparison method for manufacturing a display panel 102 with two different pixels, so that the display panel 102 provides a two-color planar-type display panel. FIGS. 3A and 3B explain the method according to the first embodiment for manufacturing a display panel 101 with two different pixels, so that the display panel 101 provides a two-color planar-type display panel. The display panel 101, 102 includes the hole transport layer 40, the longer wavelength light luminescent layer 51 such as the red light luminescent layer 51, the shorter wavelength light luminescent layer 52 such as the green light luminescent layer 52, the longer wavelength part electron transport layer 61 such as the red part electron transport layer 61, and the shorter wavelength part electron transport layer 62 such as the green part electron transport layer 62. A dopant 51d of the longer wavelength light luminescent layer 51 and a dopant 52d of the shorter wavelength light luminescent layer 52 are shown in FIGS. 2A to 3B. In FIGS. 2A to 3B, the dopants 51d, 52d represent part of the dopants, which penetrate into other portions from the predetermined region. Actually, each dopant 51d, 52d penetrates into the other portion together with the host material of the luminescent layer 50 and/or the electron transporting material of the electron transport layer 60.

In FIGS. 2A and 2B, the longer wavelength light luminescent layer 51 and the longer wavelength part electron transport layer 61 are formed before the shorter wavelength light luminescent layer 52 is formed. That is opposite to the order of the method according to the first embodiment. Specifically, the red light luminescent layer 51 is formed on the hole transport layer 40, and then the red part electron transport layer 61 is formed on the red light luminescent layer 51. Then, the green light luminescent layer 52 is formed on the hole transport layer 40, and then the green part electron transport layer 62 is formed on the green light luminescent layer 52. In this case, the dopant 51d of the red light luminescent layer 51 penetrates on the hole transport layer 40, which is disposed on the green-light-luminescent-layer-to-be-formed region and disposed next to the red light luminescent layer 51. Therefore, the dopant 51d of the red light luminescent layer 51 is disposed between the hole transport layer 40 and the green light luminescent layer 52.

The main luminous region of the luminescent layer 50 is disposed around the interface between the hole transport layer 40 and the luminescent layer 50 because the host material of the luminescent layer 50 has, in general, the electron transport property. Therefore, when the dopant 51d of the red light luminescent layer 51 penetrates between the hole transport layer 40 and the green light luminescent layer 52, the color purity of the green light luminescent layer 52 is reduced. That is because the dopant 51d of the red light luminescent layer 51 emits the red light easily compared with the dopant 52d of the green light luminescent layer 52, so that the dopant 51d in the green light luminescent layer 52 emits the red light.

On the other hand, in FIGS. 3A and 3B, the shorter wavelength light luminescent layer 52 and the shorter wavelength part electron transport layer 62 are formed before the longer wavelength light luminescent layer 51 is formed. That is the same order of the method according to the first embodiment. Specifically, the green light luminescent layer 52 is formed on the hole transport layer 40, and then the green part electron transport layer 62 is formed on the green light luminescent layer 52. Then, the red light luminescent layer 51 is formed on the hole transport layer 40, and then the red part electron transport layer 61 is formed on the red light luminescent layer 51. In this case, the dopant 52d of the green light luminescent layer 52 penetrates on the hole transport layer 40, which is disposed on the red-light-luminescent-layer-to-be-formed region and disposed next to the green light luminescent layer 52. Therefore, the dopant 52d of the green light luminescent layer 52 is disposed between the hole transport layer 40 and the red light luminescent layer 51.

When the dopant 52d of the green light luminescent layer 52 penetrates between the hole transport layer 40 and the red light luminescent layer 51, the color purity of the green light luminescent layer 52 is not reduced. That is because the dopant 52d of the green light luminescent layer 52 emits the green light hardly compared with the dopant 51d of the red light luminescent layer 51, so that the dopant 52d in the red light luminescent layer 51 does not emit the green light.

Thus, in the display panel 101, the dopant 51d of the longer wavelength light luminescent layer 51 does not exist at the interface between the shorter wavelength light luminescent layer 52 and the hole transport layer 40. Further, the dopant 51d of the longer wavelength light luminescent layer 51 does not exist at the interface between the shorter wavelength light luminescent layer 52 and the electron transport layer 60, i.e., the shorter wavelength part electron transport layer 62.

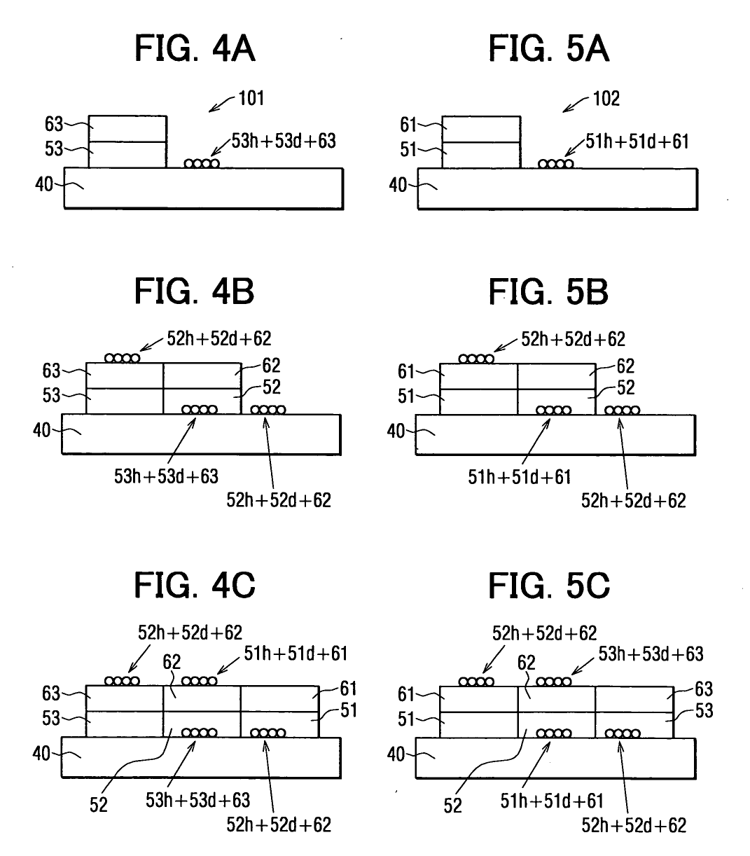

Further, the effect of the method for manufacturing the display panel 1 according to the first embodiment is described in detail as follows. FIGS. 5A to 5C explain a comparison method for manufacturing the display panel 102 with three different pixels, so that the display panel 102 provides a three-color planar-type display panel. In the display panel 102, the red, green and blue light luminescent layers 51-53 are formed on the hole transport layer 40 in this order, which is opposite to the method according to the first embodiment. FIGS. 4A to 4C explain the method according to the first embodiment for manufacturing the display panel 101 with three different pixels, so that the display panel 101 provides a three-color planar-type display panel. In the display panel 103, the blue, green and red light luminescent layers 51-53 are formed on the hole transport layer 40 in this order, which is the same order as the method according to the first embodiment.

As shown in FIG. 5C, the dopant 51d and a host material 51h of the red light luminescent layer 51 and a component of the red part electron transport layer 61 are disposed between the green light luminescent layer 52 and the hole transport layer 40. The dopant 52d and a host material 52h of the green light luminescent layer 52 and a component of the green part electron transport layer 62 are disposed between the blue light luminescent layer 53 and the hole transport layer 40. The dopant 52d and the host material 52h of the green light luminescent layer 52 and the component of the green part electron transport layer 62 are disposed on the red part electron transport layer 61, so that they will be disposed between the red part electron transport layer 61 and the cathode layer 70. A dopant 53d and a host material 53h of the blue light luminescent layer 53 and a component of the red part electron transport layer 63 are disposed on the green part electron transport layer 62, so that they will be disposed between the green part electron transport layer 62 and the cathode layer 70.

On the other hand, as shown in FIG. 4C, the dopant 53d and the host material 53h of the blue light luminescent layer 53 and the component of the blue part electron transport layer 63 are disposed between the green light luminescent layer 52 and the hole transport layer 40. The dopant 52d and the host material 52h of the green light luminescent layer 52 and the component of the green part electron transport layer 62 are disposed between the red light luminescent layer 51 and the hole transport layer 40. The dopant 52d and the host material 52h of the green light luminescent layer 52 and the component of the green part electron transport layer 62 are disposed on the blue part electron transport layer 63, so that they will be disposed between the blue part electron transport layer 63 and the cathode layer 70. The dopant 51d and the host material 51h of the red light luminescent layer 51 and the component of the red part electron transport layer 61 are disposed on the green part electron transport layer 62, so that they will be disposed between the green part electron transport layer 62 and the cathode layer 70.

In the display panel 1, the dopant 51d of the red light luminescent layer 51 does not exist at the interface between the green and blue light luminescent layers 52, 53 and the hole transport layer 40. Further, the dopant 51d of the red light luminescent layer 51 does not exist at the interface between the green and blue light luminescent layers 52, 53 and the green and blue part electron transport layers 62, 63. Further, the dopant 52d of the green light luminescent layer 52 does not exist at the interface between the blue light luminescent layer 53 and the hole transport layer 40. Further, the dopant 52d of the green light luminescent layer 52 does not exist at the interface between the blue light luminescent layer 53 and the blue part electron transport layer 63.

Therefore, the display panel 1 has high color purity. Specifically, in case of manufacturing the display panel 1, the dopant of the longer wavelength light luminescent layer is prevented from penetrating between the shorter wavelength light luminescent layer and the charge transport layer (i.e., an electron or hole transport layer) 40, 60 so that the display panel 1 is limited from decreasing the color purity.

(Second Embodiment)

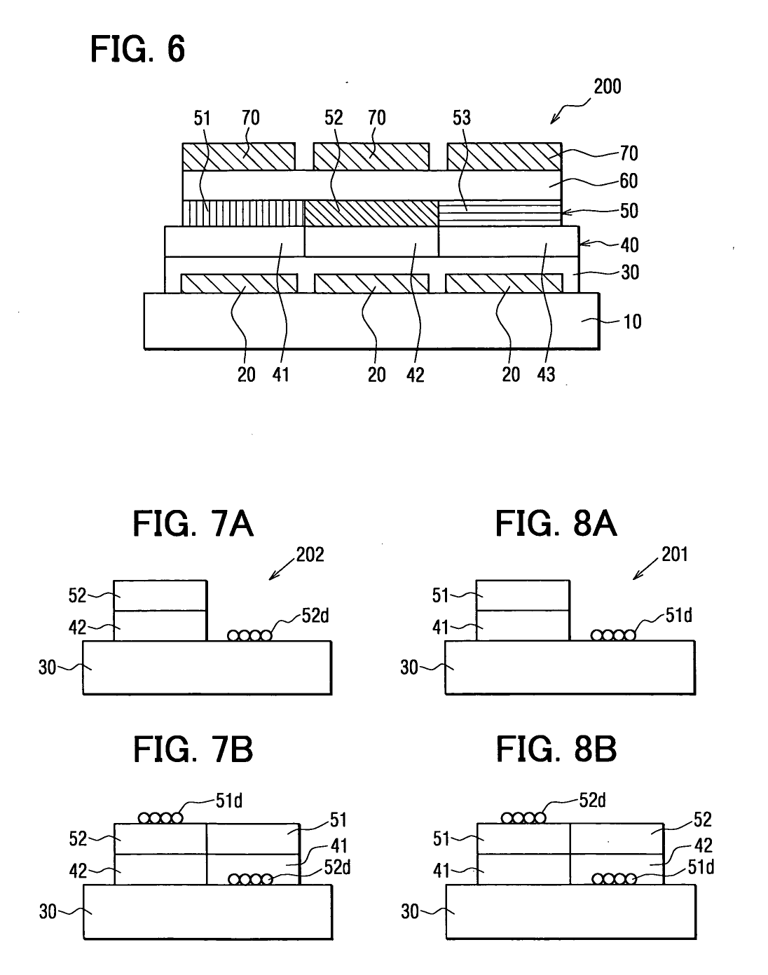

A multi-layer planar-type display panel 200 as an organic EL display panel according to a second embodiment of the present invention is shown in FIG. 6.

In this embodiment, a method for manufacturing the organic EL display panel 200 is such that one of the single-color luminescent layer 51-53 and at least the hole transport layer 40 corresponding to the single-color luminescent layer 51-53 are deposited independently from other single-color luminescent layers 51-53 so that they are deposited on a predetermined area corresponding to the single-color luminescent layer 51-53. Further, more than two layers including the single-color luminescent layer 51-53 and the hole transport layer 40 corresponding to the single-color luminescent layer 51-53 are deposited independently and separately on the predetermined area of each single-color luminescent layer 51-53.

The hole transport layer 40 is separated into three parts, which correspond to three single-color luminescent layers 51-53, respectively. Specifically, one part of the hole transport layer 40 and the single-color luminescent layer 51-53 is separately and independently deposited so that an area corresponding to the single-color luminescent layer 51-53 is formed. Here, each part of the hole transport layer 41-43 corresponds to one of the single-color luminescent layers 51-53, i.e., the red, green or blue light luminescent layers 51-53, so that the hole transport layer 40 is composed of three parts 41-43, i.e., a red, green and blue part hole transport layers 41-43.

The red, green and blue part hole transport layers 41-43 correspond to the red, green and blue light luminescent layers 51-53, and are formed on the hole injection layer 30. Each of the red, green and blue part hole transport layers 41-43, i.e., the hole transport layer 40 is made of the hole transporting material, which transports the hole and is useable for the organic EL display panel. In this embodiment, the hole transport layer 40 is made of the α-NPD film, and has a film thickness of 40 nm.

The electron transport layer 60 is formed on the red, green and blue light luminescent layers 51-53. The electron transport layer 60 is made of an electron transporting material, which is useable for the organic EL display panel. In this embodiment, the electron transport layer 60 is made of the Alq3, and has the film thickness of 20 nm.

The organic EL display panel 200 is manufactured as follows. One of the red, green and blue part hole transport layers 41-43 and one of the red, green and blue light luminescent layers 51-53 corresponding to the red, green or blue part hole transport layer 41-43 are formed sequentially so that the red, green or blue pixel is formed.

At first, the anode layer 20 made of the ITO film is formed on the substrate 10 with using the spattering method. Then, the CuPc film as the hole injection layer 30 is formed on the anode layer 20 with the film thickness of 10 nm.

Then, a mask is prepared. The mask is used for forming an organic film only on a selective area, which is preliminarily determined and corresponds to one of the red, green and blue part hole transport layers 41-43. One of the red, green and blue part hole transport layers 41-43 is formed on a predetermined area with using the mask. Then, one of the red, green or blue light luminescent layers 51-53 corresponding to the one of the hole transport layers 41-43 is formed on the one of the hole transport layers 41-43. Subsequently, another one of the hole transport layers 41-43 is formed on another predetermined area with using the mask. Then, another one of the red, green or blue light luminescent layers 51-53 corresponding to the other one of the hole transport layers 41-43 is formed on the other predetermined area. Finally, the last one of the hole transport layers 41-43 is formed on a rest area with using the mask, so that the whole hole transport layer 40 is formed. Then, the last one of the red, green or blue light luminescent layers 51-53 corresponding to the last one of the hole transport layers 41-43 is formed, so that the whole luminescent layer 50 is formed.

In this embodiment, the red, green and blue part hole transport layers 41-43 are formed in an order from the longest wavelength part hole transport layer such as the red part hole transport layer 41 to the shortest wavelength part hole transport layer such as the blue light luminescent layer 43, i.e., the red, green and blue light luminescent layers 51-53 are formed in this order. Specifically, the method for forming the hole transport layer 40 and the luminescent layer 50 is described in detail as follows.

At first, the mask is positioned on the substrate 10 so that the opening of the mask is disposed on the red-pixcel-to-be-formed region. Then, the α-NPD film is formed on the hole injection layer 30 with the film thickness of 40 nm, so that the red part hole transport layer 41 is formed on the red-pixel-to-be-formed region. Then, the Alq3 film is deposited on the red part hole transport layer 41 with the film thickness of 40 nm. Then, the DCM1 is doped with lwt % into the Alq3 film, so that the red light luminescent layer 51 is formed. Thus, the red pixel is formed.

Next, the mask is displaced at a predetermined position so that the opening of the mask is disposed on the green-pixcel-to-be-formed region. Then, the α-NPD film is formed on the hole injection layer 30 with the film thickness of 40 nm, so that the green part hole transport layer 42 is formed on the green-pixel-to-be-formed region. Then, the Alq3 film is deposited on the green part hole transport layer 42 with the film thickness of 40 nm. Then, the Quinacridone is doped with 1 wt % into the Alq3 film, so that the green light luminescent layer 52 is formed. Thus, the green pixel is formed.

At last, the mask is displaced at another predetermined position so that the opening of the mask is disposed on the blue-pixcel-to-be-formed region. Then, the α-NPD film is formed on the hole injection layer 30 with the film thickness of 40 nm, so that the blue part hole transport layer 43 is formed on the blue-pixel-to-be-formed region. Then, the BAlq film is deposited on the blue part hole transport layer 43 with the film thickness of 40 nm. Then, the Perylene is doped with 1 wt % into the BAlq film, so that the blue light luminescent layer 53 is formed. Thus, the blue pixel is formed.

After that, the Alq3 film is formed on the light luminescent layer 50 with the film thickness of 20 nm, so that the electron transport layer 60 is formed. Then, the LiF film having the film thickness of 0.5 nm and the Al film having the film thickness of 90 nm are formed successionally on the electron transport layer 60, so that the cathode layer 70 is formed. Thus, the organic EL display panel 200 is completed.

In the above method, the hole transport layer 40 and the luminescent layer 50 are formed such that each pixel is separately and independently deposited. Therefore, in each of the red-, green- or blue-pixel-to-be-formed region, both of the red, green or blue part hole transport layer 41-43 and the single-color luminescent layer 51-53 corresponding to the hole transport layer 41-43 are formed successively, separately and independently from other single-color luminescent layers 51-53. Thus, the red, green or blue hole transport layer 41-43 and the single-color luminescent layer 51-53 contact each other.

Each of the red, green or blue light luminescent layer 51-53 is formed on the red, green or blue part hole transport layers 41-43 successively, so that the dopant of the red light luminescent layer 51 as the longest wavelength light luminescent layer does not penetrate between the shorter wavelength light luminescent layer 52, 53 and its corresponding part hole transport layer 42, 43, which is next to the longest wavelength light luminescent layer 51. Specifically, the DCM1 as the dopant of the red light luminescent layer 51 does not penetrate between the green light luminescent layer 52 and the green part hole transport layer 42 nor between the blue light luminescent layer 53 and the blue part hole transport layer 43, which are next to the red light luminescent layer 51.

In this case, the dopant of the longer wavelength light luminescent layer 51 may penetrate on the hole injection layer 30, which is disposed on the shorter-wavelength-light-luminescent-layer-to-be-formed region (i.e., the green- or blue-light-luminescent-layer-to-be-formed region) and disposed next to the longer wavelength light luminescent layer 51. After that, the shorter wavelength light part hole transport layer 42, 43 and the shorter wavelength light luminescent layer 52, 53 corresponding to the formed hole transport layer 42, 43 are formed, so that the dopant of the longer wavelength light luminescent layer 51 is disposed between the hole injection layer 30 and the hole transport layer 40, and disposed under the green or blue light luminescent layer 52, 53. However, the dopant of the longer wavelength light luminescent layer 51 is not disposed between the shorter wavelength light luminescent layer 52, 53 and the green or blue part hole transport layer 42, 43

Therefore, in case of manufacturing the display panel 200, the dopant of the longest wavelength light luminescent layer 51 is prevented from penetrating between the shorter wavelength light luminescent layer 52, 53 and the hole transport layer 42, 43 so that the display panel 200 is limited from decreasing the color purity. The display panel 200 provides the RGB multi-color luminescence display panel without mixing color, which has high color purity.

Although the red, green and blue part hole transport layers 41-43 are formed in the order from the longest wavelength part hole transport layer such as the red part hole transport layer 41 to the shortest wavelength part hole transport layer such as the blue light luminescent layer 43, i.e., the red, green and blue light luminescent layers 51-53 are formed in this order, the hole transport layers 41-43 can be formed in the reverse order, i.e., the blue, green and red light luminescent layers 51-53 are formed in this order. However, preferably, the red, green and blue light luminescent layers 51-53 are formed in this order.

The effect of the method for manufacturing the display panel 200 according to the second embodiment is described as follows. FIGS. 7A and 7B explain a comparison method for manufacturing a display panel 202 with two different pixels, so that the display panel 202 provides a two-color planar-type display panel. FIGS. 8A and 8B explain the method according to the second embodiment for manufacturing a display panel 201 with two different pixels, so that the display panel 201 provides a two-color planar-type display panel. In the display panel 201, the longer wavelength light luminescent layer 51 is formed before the shorter wavelength light luminescent layer 52 is formed. That is the same order as the method according to the second embodiment. In the display panel 202, the shorter wavelength light luminescent layer 52 is formed before the longer wavelength light luminescent layer 51 is formed. That is opposite to the order of the method according to the second embodiment.

The display panel 201, 202 includes the hole injection layer 30, the longer wavelength light part hole transport layer 41 such as the red part hole transport layer 41, the shorter wavelength light part hole transport layer 42 such as the green part hole transport layer 42, the longer wavelength light luminescent layer 51 such as the red light luminescent layer 51, and the shorter wavelength light luminescent layer 52 such as the green light luminescent layer 52. The dopant 51d of the longer wavelength light luminescent layer 51 and the dopant 52d of the shorter wavelength light luminescent layer 52 are shown in FIGS. 7A to 8B. In FIGS. 7A to 8B, the dopants 51d, 52d represent part of the dopants, which penetrate into other portions from the predetermined region. Actually, each dopant 51d, 52d penetrates into the other portion together with the host material of the luminescent layer 50 and/or the hole transporting material of the hole transport layer 40.

In FIGS. 7A and 7B, the shorter wavelength part hole transport layer 42 and the shorter wavelength light luminescent layer 52 are formed before the longer wavelength light part hole transport layer 41 and the longer wavelength light luminescent layer 51 is formed. Specifically, the green part hole transport layer 42 is formed on the hole injection layer 30, and then the green light luminescent layer 52 is formed on the green part hole transport layer 42. Then, the red part hole transport layer 41 is formed on the hole injection layer 30, and then the red light luminescent layer 51 is formed on the red part hole transport layer 41. In this case, the dopant 51d of the red light luminescent layer 51 does not penetrate between the green light luminescent layer 52 and the green part hole transport layer 42. However, the dopant 51d of the red light luminescent layer 51 penetrates between the green light luminescent layer 52 and the electron transport layer 60, which is disposed on the luminescent layer 50. Here, the main luminous region of the luminescent layer 50 is disposed around the interface between the hole transport layer 40 and the luminescent layer 50. Therefore, the dopant 51d of the red light luminescent layer 51 is disposed at the interface between the electron transport layer 60 and the luminescent layer 50, which is not the main luminous region. However, the dopant 51d may affect the green light luminescent layer 52 so that the color purity of the green light emitted from the green light luminescent layer 52 is reduced a little.

On the other hand, in FIGS. 8A and 8B, the longer wavelength light part hole transport layer 41 and the longer wavelength light luminescent layer 51 are formed before the shorter wavelength light luminescent layer 52 is formed. Specifically, the red part hole transport layer 41 is formed on the hole injection layer 30, and then the red light luminescent layer 51 is formed on the red part hole transport layer 41. Then, the green part hole transport layer 42 is formed on the hole injection layer 30, and then the green light luminescent layer 52 is formed on the green part hole transport layer 42. In this case, the dopant 52d of the green light luminescent layer 52 penetrates on the red light luminescent layer 51, which is next to the green light luminescent layer 52. Therefore, the dopant 52d of the green light luminescent layer 52 is disposed between the electron transport layer 60 and the red light luminescent layer 51.

When the dopant 52d of the green light luminescent layer 52 penetrates between the electron transport layer 60 and the red light luminescent layer 51, the color purity of the red light luminescent layer 51 is not reduced. That is because the dopant 52d of the green light luminescent layer 52 emits the green light hardly compared with the dopant 51d of the red light luminescent layer 51, so that the dopant 52d on the red light luminescent layer 51 does not emit the green light.

Further, the dopant 51d of the red light luminescent layer 51 is not disposed at the interface between the green light luminescent layer 52 and the electron transport layer 60, so that the color purity of the light emitted from the green light luminescent layer 52 is prevented from decreasing.

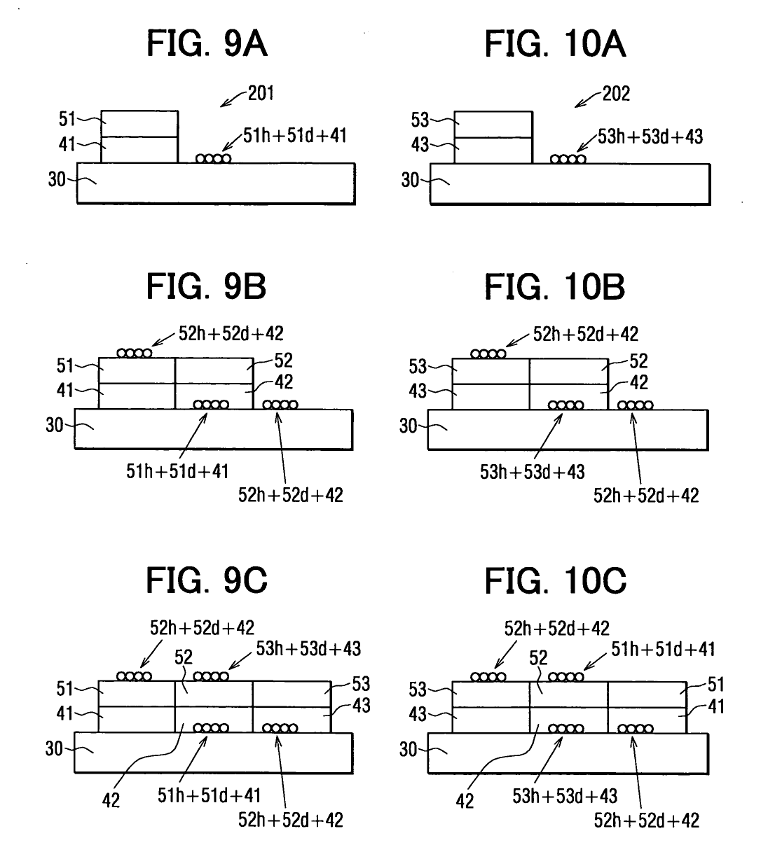

Further, the effect of the method for manufacturing the display panel 200 according to the second embodiment is described in detail as follows. FIGS. 10A to 10C explain a comparison method for manufacturing the display panel 202 with three different pixels, so that the display panel 202 provides a three-color planar-type display panel. In the display panel 202, the blue, green and red part hole transport layers 41-43 and the blue, green and red light luminescent layers 51-53 are formed on the hole injection layer 30 in this order, which is opposite to the method according to the second embodiment. FIGS. 9A to 9C explain the method according to the second embodiment for manufacturing the display panel 201 with three different pixels, so that the display panel 201 provides a three-color planar-type display panel. In the display panel 201, the red, green and blue part hole transport layers 41-43 and the red, green and blue light luminescent layers 51-53 are formed on the hole injection layer 30 in this order, which is the same order as the method according to the second embodiment.

As shown in FIG. 1° C., the dopant 53d and the host material 53h of the blue light luminescent layer 53 and a component of the blue part hole transport layer 43 are disposed between the green part hole transport layer 42 and the hole injection layer 30. The dopant 52d and the host material 52h of the green light luminescent layer 52 and a component of the green part hole transport layer 42 are disposed between the red part hole transport layer 41 and the hole injection layer 30. The dopant 52d and the host material 52h of the green light luminescent layer 52 and the component of the green part hole transport layer 42 are disposed on the blue light luminescent layer 53, so that they will be disposed between the blue light luminescent layer 53 and the electron transport layer 60. The dopant 51d and the host material 51h of the red light luminescent layer 51 and a component of the red part hole transport layer 41 are disposed on the green light luminescent layer 52, so that they will be disposed between the green light luminescent layer 52 and the electron transport layer 60.

On the other hand, as shown in FIG. 9C, the dopant 51d and the host material 51h of the red light luminescent layer 51 and the component of the red part hole transport layer 41 are disposed between the green part hole transport layer 42 and the hole injection layer 30. The dopant 52d and the host material 52h of the green light luminescent layer 52 and the component of the green part hole transport layer 42 are disposed between the blue part hole transport layer 43 and the hole injection layer 30. The dopant 52d and the host material 52h of the green light luminescent layer 52 and the component of the green part hole transport layer 42 are disposed on the red light luminescent layer 51, so that they will be disposed between the red light luminescent layer 51 and the electron transport layer 60. The dopant 53d and the host material 53h of the blue light luminescent layer 53 and the component of the blue part hole transport layer 43 are disposed on the green light luminescent layer 52, so that they will be disposed between the green light luminescent layer 52 and the electron transport layer 60.

Thus, in the display panel 200, the dopant 51d of the longer wavelength light luminescent layer 51 does not exist at the interface between the shorter wavelength light luminescent layer 52 and the hole transport layer 40.

In the display panel 200, the dopant 51d of the red light luminescent layer 51 does not exist at the interface between the green and blue light luminescent layers 52, 53 and the hole transport layer 40. Further, the dopant 51d of the red light luminescent layer 51 does not exist at the interface between the green and blue light luminescent layers 52, 53 and the electron transport layer 60. Further, the dopant 52d of the green light luminescent layer 52 does not exist at the interface between the blue light luminescent layer 53 and the hole transport layer 40. Further, the dopant 52d of the green light luminescent layer 52 does not exist at the interface between the blue light luminescent layer 53 and the electron transport layer 60.

Therefore, the display panel 200 has high color purity. Specifically, in case of manufacturing the display panel 200, the dopant of the longer wavelength light luminescent layer is prevented from penetrating between the shorter wavelength light luminescent layer and the charge transport layer (i.e., an electron or hole transport layer) 40, 60 so that the display panel 200 is limited from decreasing the color purity.

Although the methods for manufacturing the organic EL display panel 1, 200 are such that one of the single-color luminescent layers 51-53 and one of the charge transport layer, i.e., the electron or hole transport layer 40, 60, corresponding to the single-color luminescent layer 51-53 are deposited successively, separately and independently from other single-color luminescent layers 51-53, the single-color luminescent layer 51-53 and both of the electron and hole transport layers 40, 60 can be deposited successively and independently from other single-color luminescent layers 51-53.

In this case, the electron transport layer 60 is composed of three part electron transport layers 61-63, and the hole transport layer 40 is composed of three part hole transport layers 41-43. One of the three part hole transport layers 41-43, one of the single-color luminescent layers 51-53 corresponding to the one of the three part hole transport layers 41-43, and one of the three part electron transport layers 61-63 corresponding to the one of the three part hole transport layers 41-43 are formed successively, separately and independently from other single-color luminescent layers 51-53 so that an area corresponding to the single-color luminescent layer 51-53 is formed.

Specifically, after the anode layer 20 and the hole injection layer 30 are formed, the red part hole transport layer 41, the red light luminescent layer 51 and the red part electron transport layer 61 are formed in this order on the hole injection layer 30, which is disposed on the red-light-luminescent-layer-to-be-formed region. Then, the green part hole transport layer 42, the green light luminescent layer 52 and the green part electron transport layer 62 are formed in this order on the hole injection layer 30, which is disposed on the green-light-luminescent-layer-to-be-formed region. Then, the blue part hole transport layer 43, the blue light luminescent layer 53 and the blue part electron transport layer 63 are formed in this order on the hole injection layer 30, which is disposed on the blue-light-luminescent-layer-to-be-formed region. After that, the cathode layer 70 is formed on the whole electron transport layer 60. Thus, the display panel is completed. In this case, the dopant of the longer wavelength light luminescent layer 51 does not penetrate between the shorter wavelength light luminescent layer 52, 53 and the hole transport layer 42, 43. Further, the dopant of the longer wavelength light luminescent layer 51 does not penetrate between the shorter wavelength light luminescent layer 52, 53 and the electron transport layer 62, 63. Thus, the color purity of each pixel in the display panel is prevented from decreasing.

(Third Embodiment)

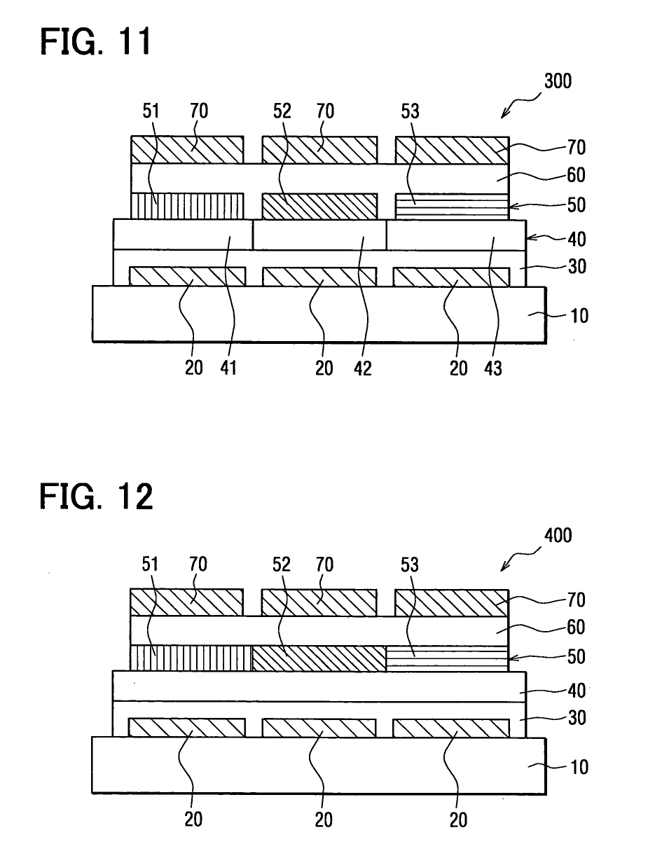

A multi-layer planar-type display panel 300 as an organic EL display panel according to a third embodiment of the present invention is shown in FIG. 11. The display panel 300 includes three parts of the charge transport layer and the three single-color luminescent layers 51-53. Each part of the charge transport layer has a larger area, which is larger than that of the single-color luminescent layer 51-53. Specifically, an opening of a mask for forming each part of the charge transport layer is larger than that of a mask for forming the single-color luminescent layer 51-53. In the third embodiment, the mask for forming the red, green and blue part hole transport layers 41-43 has a large opening, which is larger than that of the mask for forming the red, green and blue light luminescent layers 51-53, so that the area of each of the red, green and blue part hole transport layers 41-43 is larger than that of the red, green and blue light luminescent layers 51-53.

The red, green and blue part hole transport layers 41-43 pack together, i.e., are deposited in high density so that the layers are closely disposed on the hole injection layer 30 as close as possible. Therefore, part of the electron transport layer 60 disposed between the red, green and blue light luminescent layers 51-53 is formed securely so that total film thickness between the anode and cathode layers (i.e., upper and lower electrode layers) 20, 70 is sufficiently secured. Thus, a short circuit between the anode and cathode layers 20, 70 is prevented.

The above method can be applied to a display panel, which includes three parts of the electron transport layer 61-63 and the three single-color luminescent layers 51-53. In this case, an area of each of the red, green and blue part electron transport layers 61-63 is larger than that of the red, green and blue light luminescent layers 51-53.

(Fourth Embodiment)

A multi-layer planar-type display panel 400 as an organic EL display panel according to a fourth embodiment of the present invention is shown in FIG. 12. In this embodiment, at least one of the red, green and blue light luminescent layers 51-53 includes at least one of hole transporting materials as a host material of the luminescent layer 50.

The luminescent layer 50 is formed on the hole transport layer 40, and is made of a luminous material, which is useable for the organic EL display panel. Specifically, the luminescent layer 50 is formed of a host material and a various dopant as a fluorescent dye. Mainly, the color of the light emitted at the luminescent layer 50 depends on the dopant.

In this embodiment, the red light luminescent layer 51 is made of a host material including the Alq3 and the NPD and a dopant of the DCM1. Specifically, the host material is made of the mixture of Alq3 and NPD, which has the ratio of Alq3 to NPD of 3:1. Here, the Alq3 is the electron transporting material, and the NPD is the hole transporting material. Then, the DCM1 is doped in the host material with 1 wt %. The film thickness of the red light luminescent layer 51 is about 40 nm. The green light luminescent layer 52 is made of a host material including the Alq3 and the NPD and a dopant of the Quinacridone. The host material is made of the mixture of Alq3 and NPD, which has the ratio of Alq3 to NPD of 3:1. The Quinacridone is doped in the host material with 1 wt %. The film thickness of the green light luminescent layer 52 is about 40 nm. The blue light luminescent layer 53 is made a host material including the BAlq and the NPD and a dopant of the Perylene. The host material is made of the mixture of BAlq and NPD, which has the ratio of BAlq to NPD of 3:1. The Perylene is doped in the host material with 1 wt %. The film thickness of the blue light luminescent layer 53 is about 40 nm.

The organic EL display panel 400 is manufactured as follows. At first, the ITO film is formed on the substrate 10 with using the spattering method. Then, the ITO film is patterned into a predetermined pattern with using a photolithography method, so that the anode layer 20 is formed. Then, the CuPc film as the hole injection layer 30 is formed on the anode layer 20 with the film thickness of 10 nm with using the vapor deposition method. Then, the NPD film as the hole transport layer 40 is formed on the CuPc film with the film thickness of 40 nm.

Then, a mask is prepared. The mask is used for forming an organic film only on a selective area, which is preliminarily determined and corresponds to one of the red, green and blue light luminescent layers 51-53. One of the red, green and blue light luminescent layers 51-53 is formed on a predetermined area with using the mask. Subsequently, another single-color luminescent layer 51-53 is formed on another predetermined area with using the mask. Finally, the last one of the single-color luminescent layers 51-53 is formed on a rest area with using the mask, so that the whole luminescent layer 50 is formed.

Thus, the single-color luminescent layers 51-53 are formed separately and independently. The mask is made of glass or metal such as stainless steel having an opening corresponding to the single-color luminescent layer 51-53. The single-color luminescent layers 51-53 are formed with using the vapor deposition method. In this embodiment, the single-color luminescent layers 51-53 are formed in an order from the shortest wavelength light luminescent layer such as the blue light luminescent layer 53 to the longest wavelength light luminescent layer such as the red light luminescent layer 51, i.e., the blue, green and red light luminescent layers 51-53 are formed in this order. Specifically, the method for forming the luminescent layer 50 is described in detail as follows.

At first, the mask is positioned on the substrate 10 so that the opening of the mask is disposed on a blue-pixcel-to-be-formed region. Then, the BAlq film and the NPD film are deposited together with using vapor co-deposition method with the film thickness of 40 nm. The co-deposition of the BAlq film and the NPD film is performed with the ratio of BAlq to NPD of 3:1. Then, the Perylene is doped with 1 wt % into the host material (i.e., the mixture of the BAlq film and the NPD film), so that the blue light luminescent layer 53 is formed. Thus, the blue pixel is formed.

Next, the mask is displaced at a predetermined position so that the opening of the mask is disposed on a green-pixcel-to-be-formed region. Then, the Alq3 film and the NPD film are deposited together with using the vapor co-deposition method with the film thickness of 40 nm. The co-deposition of the Alq3 film and the NPD film is performed with the ratio of Alq3 to NPD of 3:1. Then, the Quinacridone is doped with 1 wt % into the host material (i.e., the mixture of the Alq3 film and the NPD film), so that the green light luminescent layer 52 is formed. Thus, the green pixel is formed.

At last, the mask is displaced at another predetermined position so that the opening of the mask is disposed on a red-pixcel-to-be-formed region. Then, the Alq3 film and the NPD film are deposited together with using the vapor co-deposition method with the film thickness of 40 nm. The co-deposition of the Alq3 film and the NPD film is performed with the ratio of Alq3 to NPD of 3:1. Then, the DCM1 is doped with 1 wt % into the host material, so that the red light luminescent layer 51 is formed. Thus, the red pixel is formed.

After that, the Alq3 film is formed on the luminescent layer 50 with the film thickness of 20 nm, so that the electron transport layer 60 is formed. Then, the LiF film having the film thickness of 0.5 nm and the Al film having the film thickness of 90 nm are formed successionally on the electron transport layer 60, so that the cathode layer 70 is formed. Thus, the organic EL display panel 400 is completed.

In this embodiment, the hole transporting material in the host material of the single-color luminescent layer 50 firstly deposited penetrates on the hole transport layer 40, which is next to the firstly deposited single-color luminescent layer 51-53 and disposed on another single-color-luminescent-layer-to-be-formed region. Therefore, the hole transporting material as the host material of the firstly deposited single-color luminescent layer 51-53 is disposed between the other single-color luminescent layer 51-53 next to the firstly deposited single-color luminescent layer 51-53 and the hole transport layer 40. Specifically, for example, in a case where the blue light luminescent layer 53 is formed firstly, and then the green light luminescent layer 52 is formed, advantages of the display panel 400 are described as follows.

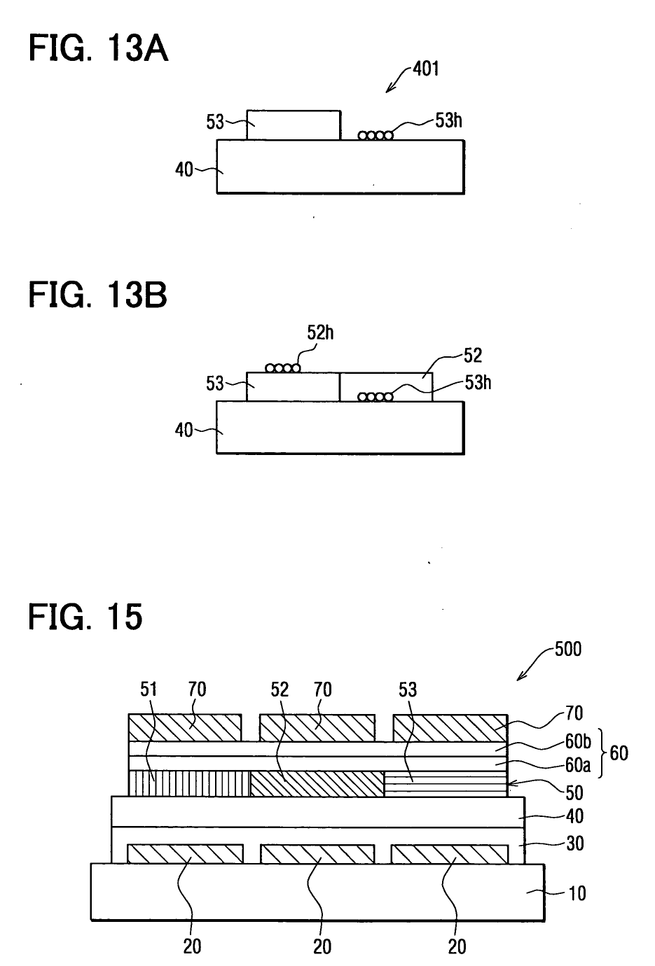

FIGS. 13A and 13B explain the manufacturing process of a display panel 401. When the blue light luminescent layer 53 is deposited on the hole transport layer 40 firstly, the host material 53h of the blue light luminescent layer 53, specifically, the NPD as the hole transporting material penetrates on the hole transport layer 40, which is next to the blue light luminescent layer 53 and disposed on the green-light-luminescent-layer-to-be-formed region. Then, the green light luminescent layer 52 is deposited on the green-light-luminescent-layer-to-be-formed region. Therefore, the NPD as the hole transporting material in the host material 53h of the blue light luminescent layer 53 is disposed at an interface between the green light luminescent layer 52 and the hole transport layer 40, as shown in FIG. 13B. Here the host material 52h of the green light luminescent layer 52 includes the NPD, which penetrates and is disposed on the blue light luminescent layer 53.

A hole delivered from the hole transport layer 40 toward the green light luminescent layer 52 is delivered to the green light luminescent layer 52 effectively and smoothly, because the NPD disposed between the green light luminescent layer 52 and the hole transport layer 40 assists to deliver the hole. On the other hand, in the display panel 1000 shown in FIG. 17, the host material of the blue light luminescent layer 53 is composed of the Alq3, so that the Alq3 as the electron transporting material penetrates and is disposed between the green light luminescent layer 52 and the hole transport layer 40. Therefore, the hole delivered from the hole transport layer 40 toward the green light luminescent layer 52 is disturbed from being delivered to the green light luminescent layer 52.

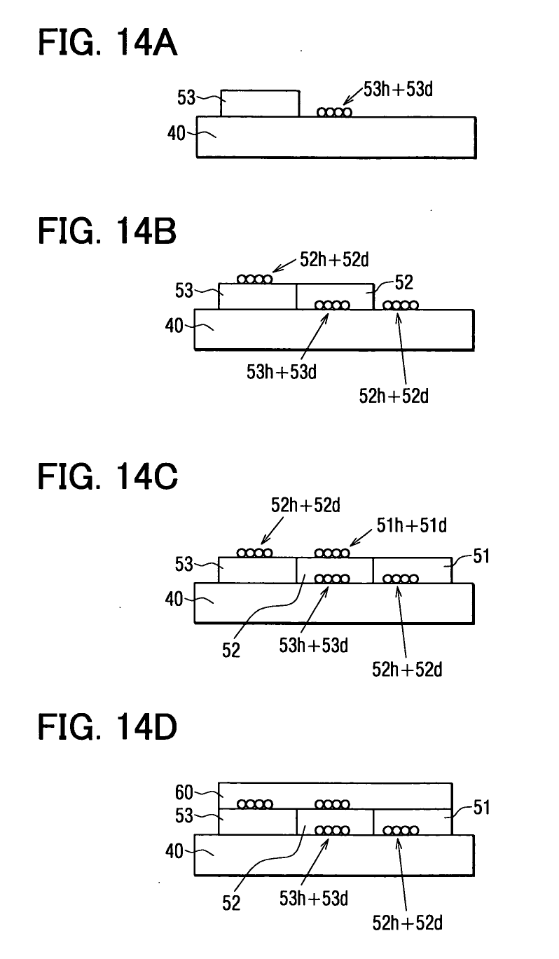

Further, the effect of the method for manufacturing the display panel 400 according to the fourth embodiment is described in detail as follows. FIGS. 14A to 14D explain the method for manufacturing the display panel 401 with three different pixels, so that the display panel 401 provides a three-color planar-type display panel. In the display panel 401, the blue, green and red light luminescent layers 51-53 are formed on the hole transport layer 40 in this order.

As shown in FIG. 14D, the dopant 53d and the host material 53h of the blue light luminescent layer 53 are disposed between the green light luminescent layer 52 and the hole transport layer 40. The dopant 52d and the host material 52h of the green light luminescent layer 52 are disposed between the red light luminescent layer 51 and the hole transport layer 40. The dopant 52d and the host material 52h of the green light luminescent layer 52 are disposed between the blue light luminescent layer 53 and the electron transport layer 60. The dopant 51d and the host material 51h of the red light luminescent layer 51 are disposed between the green light luminescent layer 52 and the electron transport layer 60.

In the display panel 400, even if the host material 51h, 52h of the single-color luminescent layer 51, 52 penetrates between the hole transport layer 40 and the other single-color luminescent layers 51-53, the host material includes the hole transporting material so that the luminous efficiency of each single-color luminescent layer 51-53 is improved. Here, the luminous efficiency of the display panel 400 is 2.5 cd/A (i.e., 2.5 Candela per Ampere), and the luminous efficiency of the display panel 1000 is 2.2 cd/A. Therefore, the improvement of the luminous efficiency is about 13%.

Thus, the display panel 400 has high luminous efficiency. Specifically, in case of manufacturing the display panel 400, even if the host material of one of the single-color luminescent layers 51-53 adheres to an interface between another single-color luminescent layer and the hole transport layer, the display panel 400 is limited from decreasing the luminous efficiency. Here, the one single-color luminescent layer is adjacent to the other single-color luminescent layer, and the one and the other single-color luminescent layers emit different lights having different colors, respectively.

Although all of the single-color luminescent layers 51-53 include the hole transporting material as the host material, it is not necessary to include the hole transporting material into all layers 51-53 in a case where the single-color luminescent layer 51-53 without penetrating the host material exists or a case where it is not required to prevent from mixing the colors of all of the lights. For example, the red light luminescent layer 51 is formed at last. Therefore, the host material of the red light luminescent layer 51 may be composed of the Alq3 only. That is, the red light luminescent layer 51 may not include the NPD. Specifically, it is necessitated that the blue and green light luminescent layers 52, 53 including the hole transporting material are formed before the red light luminescent layer 51 without including the hole transporting material is formed.

Preferably, the shorter wavelength light luminescent layer is formed firstly, and then the longer wavelength light luminescent layer is formed. In this case, the dopant of the longer wavelength light luminescent layer does not penetrate between the shorter wavelength light luminescent layer and the hole transport layer 40. That is on the basis of a well-known art that the host material of the luminescent layer 50 has, in general, the electron transporting property. Specifically, the host material of the luminescent layer 50 is mainly made of the electron transporting material, so that the luminous region for emitting the light by recombination of the charge is mainly disposed around the interface between the hole transport layer 40 and the luminescent layer 50. Therefore, the host material of the longer wavelength light luminescent layer does not penetrate between the shorter wavelength light luminescent layer and the hole transport layer 40 in a case where the shorter wavelength light luminescent layer is firstly deposited on the hole transport layer 40. Thus, the mixture of color of light emitted from the luminescent layer 50 is prevented.

Further, if possible, all of the host material of the luminescent layer 50 may be composed of only the hole transporting material.

(Fifth Embodiment)

A multi-layer planar-type display panel 500 as an organic EL display panel according to a fifth embodiment of the present invention is shown in FIG. 15. The display panel 500 includes a hole block layer. Specifically, the display panel 500 includes the electron transport layer 60 having the first and second electron transport layers 60a, 60b. The first electron transport layer 60a is made of an electron transporting material having higher ionization potential (i.e., ionization energy), which is higher than that of the hole transporting material composing the luminescent layer 50. Here, at least one of the single-color luminescent layers 51-53 includes the hole transporting material and the electron transporting material. Specifically, the ionization energy of the electron transporting material of the first electron transport layer 60a is 0.2 eV higher than that of the hole transporting material in the luminescent layer 50. That is, the difference of the ionization potential between the electron transporting material and the hole transporting material is equal to or larger than 0.2 eV. Therefore, the first electron transport layer 60a works as the hole block layer for blocking the hole delivered from the luminescent layer 50. The first electron transport layer 60a is made of the BAlq, which is the host material of the blue light luminescent layer 53 and is the electron transporting material. The film thickness of the first electron transport layer 60a is about 20 nm.

The second electron transport layer 60b is formed on the first electron transport layer 60a, and is made of the electron transporting material, which is useable for the organic EL display panel. In this embodiment, the second electron transport layer 60b is made of the Alq3 film, and the film thickness is 20 nm.

When the host material of the luminescent layer 50 includes the hole transporting material, the center of a luminous distribution is disposed on the electron transport layer side (i.e., on the upper electrode side) instead of the hole transport layer side. That is, the luminous region is mainly disposed on the electron transport layer side. That is because the transport capacity of hole in the hole transporting material of the luminescent layer 50 is larger than the transport capacity of electron in the electron transporting material of the luminescent layer 50. This relationship of the ionization potential between the hole transporting material and the electron transporting material in the luminescent layer 50 is obvious and well-known. Therefore, if the display panel 500 does not include the hole block layer, the luminous efficiency of the display panel 500 may be reduced, and the lifetime of luminance of the display panel 500 may be decreased.

Thus, the display panel 500 has high luminous efficiency.

Preferably, as described above, the first electron transport layer 60a can be made of only the electron transporting material, which is one of the host material composing the luminescent layer 50. In this case, the number of the material for forming the display panel 500 is reduced, so that the manufacturing process is simplified. Therefore, the manufacturing cost is reduced. However, the first electron transport layer 60a can be made of other electron transporting materials as long as the ionization potential of the electron transporting material is 0.2 ev higher than that of the hole transporting material in the luminescent layer 50.

Such changes and modifications are to be understood as being within the scope of the present invention as defined by the appended claims.

What is claimed is:

1. An organic electro luminescence display panel comprising:
a hole transport layer; and
a luminescent layer disposed on the hole transport layer,
wherein the luminescent layer includes at least first and second luminescent layers,
wherein the first and second luminescent layers are repeatedly arranged on the hole transport layer so as to be adjacent each other,
wherein the first luminescent layer includes a first dopant for emitting a first light having a first wavelength, and the second luminescent layer includes a second dopant for emitting a second light having a second wavelength, which is shorter than the first wavelength, and
wherein no first dopant is disposed between the hole transport layer and the second luminescent layer.

2. The display panel according to claim 1, further comprising:
a substrate;
an anode layer;
an electron transport layer; and
a cathode layer,
wherein the anode layer, the hole transport layer, the luminescent layer, the electron transport layer and the cathode layer are disposed on the substrate in this order.

3. The display panel according to claim 1,
wherein the hole transport layer includes a plurality of parts of the hole transport layer.

4. The display panel according to claim 2, further comprising:
a hole injection layer disposed between the anode layer and the hole transport layer.

5. The display panel according to claim 3,
wherein the parts of the hole transport layer include at least first and second part hole transport layers, which correspond to the first and second luminescent layers, respectively, and
wherein both of the first luminescent layer and the first part hole transport layer are formed independently from the second luminescent layer and the second part hole transport layer.

6. The display panel according to claim 5,
wherein one of the first and second luminescent layers and one part of the hole transport layer corresponding to the one of the first and second luminescent layers are successively formed so that no dopant of the other one of the first and second luminescent layers is disposed between the one part of the hole transport layer and the one of the first and second luminescent layers.

7. The display panel according to claim 6,
wherein the first luminescent layer is formed with using a time-sharing method before the second luminescent layer is formed.

8. The display panel according to claim 3,
wherein the luminescent layer further includes a third luminescent layer, which includes a third dopant for emitting a third light having a third wavelength,
wherein the first light is a red light, the second light is a green light, and the third light is a blue light, and
wherein the first, second and third luminescent layers are repeatedly arranged on the hole transport layer so as to be adjacent together.

9. The display panel according to claim 2,
wherein no first dopant is disposed between the electron transport layer and the second luminescent layer.

10. The display panel according to claim 9,
wherein the electron transport layer includes a plurality of parts of the electron transport layer.

11. The display panel according to claim 9, further comprising:
a hole injection layer disposed between the anode layer and the hole transport layer.

12. The display panel according to claim 10,
wherein the parts of the electron transport layer include at least first and second part electron transport layers, which correspond to the first and second luminescent layers, respectively, and
wherein both of the first luminescent layer and the first part electron transport layer are formed independently from the second luminescent layer and the second electron transport layer.

13. The display panel according to claim 12,
wherein one of the first and second luminescent layers and one part of the electron transport layer corresponding to the one of the first and second luminescent layers are successively formed so that no dopant of the other one of the first and second luminescent layers is disposed between the one part of the electron transport layer and the one of the first and second luminescent layers.

14. The display panel according to claim 13,
wherein the second luminescent layer is formed on the hole transport layer with using a time-sharing method before the first luminescent layer is formed on the hole transport layer.

15. The display panel according to claim 9,
wherein the luminescent layer further includes a third luminescent layer, which includes a third dopant for emitting a third light having a third wavelength,
wherein the first light is a red light, the second light is a green light, and the third light is a blue light, and
wherein the first, second and third luminescent layers are repeatedly arranged on the hole transport layer so as to be adjacent together.

16. An organic electro luminescence display panel comprising:
a hole transport layer; and
a luminescent layer disposed on the hole transport layer,
wherein the luminescent layer includes at least first and second luminescent layers,
wherein the first and second luminescent layers are repeatedly arranged on the hole transport layer so as to be adjacent each other, and
wherein at least one of the first and second luminescent layers includes a hole transporting material as a host material.

17. The display panel according to claim 16, further comprising:
a substrate;
an anode layer;
an electron transport layer; and
a cathode layer,
wherein the anode layer, the hole transport layer, the luminescent layer, the electron transport layer and the cathode layer are disposed on the substrate in this order, and
wherein the first luminescent layer includes a first dopant for emitting a first light having a first wavelength, and the second luminescent layer includes a second dopant for emitting a second light having a second wavelength, which is shorter than the first wavelength.

18. The display panel according to claim 16,
wherein the hole transporting material of the one of the first and second luminescent layers is disposed at an interface between the other one of the first and second luminescent layers and the hole transport layer.

19. The display panel according to claim 18,
wherein the interface further includes an electron transporting material for composing the other one of the first and second luminescent layers.

20. The display panel according to claim 17,
wherein the second luminescent layer is formed on the hole transport layer with using a time-sharing method before the first luminescent layer is formed on the hole transport layer.

21. The display panel according to claim 17,
wherein the luminescent layer further includes a third luminescent layer, which includes a third dopant for emitting a third light having a third wavelength,
wherein the first light is a red light, the second light is a green light, and the third light is a blue light, and
wherein the first, second and third luminescent layers are repeatedly arranged on the hole transport layer so as to be adjacent together.

22. The display panel according to claim 16,
wherein the electron transport layer is made of an electron transporting material having an ionization potential, and
wherein the hole transporting material in the one of the first and second luminescent layers has another ionization potential, which is 0.2 eV lower than that of the electron transporting material in the electron transport layer.

23. The display panel according to claim 22,
wherein both of the first and second luminescent layers are made of the electron transporting material as a host material.

24. A method for manufacturing an organic electro luminescence display panel, which includes a hole transport layer and a luminescent layer disposed on the hole transport layer, wherein the luminescent layer includes at least first and second luminescent layers, which are repeatedly arranged on the hole transport layer so as to be adjacent each other, and wherein one of the first and second layers includes a hole transporting material as a host material, the method comprising the step of:
forming the one of the first and second luminescent layers on the hole transport layer; and
forming the other one of the first and second luminescent layers on the hole transport layer after the step of forming the one of the first and second luminescent layers.

25. The method according to claim 24,
wherein the first luminescent layer includes a first dopant for emitting a first light having a first wavelength, and the second luminescent layer includes a second dopant for emitting a second light having a second wavelength, which is shorter than the first wavelength, and
wherein the second luminescent layer is formed on the hole transport layer before the first luminescent layer is formed on the hole transport layer.

26. The method according to claim 25,
wherein the display panel further includes a substrate, an anode layer, an electron transport layer and a cathode layer, and
wherein the anode layer, the hole transport layer, the luminescent layer, the electron transport layer and the cathode layer are disposed on the substrate in this order.

27. The method according to claim 24,
wherein the hole transporting material of the one of the first and second luminescent layers is disposed at an interface between the other one of the first and second luminescent layers and the hole transport layer.

28. The method according to claim 27,
wherein the interface further includes an electron transporting material for composing the other one of the first and second luminescent layers.

29. The method according to claim 26,
wherein the luminescent layer further includes a third luminescent layer, which includes a third dopant for emitting a third light having a third wavelength,
wherein the first light is a red light, the second light is a green light, and the third light is a blue light, and
wherein the first, second and third luminescent layers are repeatedly arranged on the hole transport layer so as to be adjacent together.

30. A method for manufacturing an organic electro luminescence display panel, which includes a hole transport layer and a luminescent layer disposed on the hole transport layer, wherein the luminescent layer includes at least first and second luminescent layers, which are repeatedly arranged on the hole transport layer so as to be adjacent each other, and wherein the hole transport layer includes at least first and second part hole transport layers, which correspond to the first and second luminescent layers, respectively, the method comprising the step of:
forming one of the first and second part hole transport layers;
forming one of the first and second luminescent layers on the one of the first and second part hole transport layers;
forming the other one of the first and second part hole transport layers; and
forming the other one of the first and second luminescent layers on the other one of the first and second part hole transport layers.

31. The method according to claim 30,
wherein both of the first luminescent layer and the first part hole transport layer are formed independently from the second luminescent layer and the second part hole transport layer, and
wherein the first luminescent layer is formed successively on the first part hole transport layer, and the second luminescent layer is formed successively on the second part hole transport layer.

32. The method according to claim 31,
wherein the display panel further includes a substrate, an anode layer, an electron transport layer and a cathode layer, and
wherein the anode layer, the hole transport layer, the luminescent layer, the electron transport layer and the cathode layer are disposed on the substrate in this order.

33. The method according to claim 32,
wherein the first luminescent layer includes a first dopant for emitting a first light having a first wavelength, and the second luminescent layer includes a second dopant for emitting a second light having a second wavelength, which is shorter than the first wavelength, and
wherein the second luminescent layer is formed before the first luminescent layer is formed.

34. The method according to claim 33,
wherein the luminescent layer further includes a third luminescent layer, which includes a third dopant for emitting a third light having a third wavelength,
wherein the first light is a red light, the second light is a green light, and the third light is a blue light,
wherein the hole transport layer further includes a third part hole transport layer, which corresponds to the third luminescent layer,
wherein the first, second and third luminescent layers are repeatedly arranged on the hole transport layer so as to be adjacent together,
wherein the one of the first and second part hole transport layers is the first part hole transport layer, and the one of the first and second luminescent layers is the first luminescent layer,
wherein the other one of the first and second part hole transport layers is the second part hole transport layer, and the other one of the first and second luminescent layers is the second luminescent layer,
wherein the method further comprising:
forming the third part hole transport layer; and
forming the third luminescent layer successively on the third part hole transport layer, and
wherein the third, second and first luminescent layers are formed in this order.
